(19) United States
(12) Patent Application Publication
(10) Pub. No.: US 2025/0168998 A1
(43) Pub. Date: May 22, 2025

(54) DISPLAY DEVICE

(71) Applicant: LG ELECTRONICS INC., Seoul (KR)

(72) Inventors: Juhyun LEE, Seoul (KR); Youngtae IM, Seoul (KR); Youngwook KANG, Seoul (KR)

(73) Assignee: LG ELECTRONICS INC., Seoul (KR)

(21) Appl. No.: 18/952,268

(22) Filed: Nov. 19, 2024

(30) Foreign Application Priority Data
Nov. 20, 2023 (KR) 10-2023-0160951

(51) Int. Cl. H05K 5/02; B32B 3/26; B32B 5/02

(52) U.S. Cl. CPC H05K 5/0217; B32B 3/266; B32B 5/02; B32B 2250/40; B32B 2457/20

(57) ABSTRACT

A display device is disclosed. The display device includes: a display panel; a material complexed plate to which the display panel is coupled; and a coupling member coupled to the material complexed plate, wherein the material complexed plate includes: a front skin that defines a front surface of the material complexed plate; a rear skin that defines a rear surface of the material complexed plate, the rear skin facing the front skin; a core positioned between the front skin and the rear skin, the core including fibers; and a coupling hole formed through the front skin, the rear skin, and the core, and the coupling member includes: an outer shell inserted into the coupling hole and coupled to at least one of the front skin or the rear skin; and an inner solid inserted into the outer shell and coupled to the outer shell.

### CROSS-REFERENCE TO RELATED APPLICATION(S)

Pursuant to 35 U.S.C. § 119, this application claims the benefit of earlier filing date and right of priority to Korean Application No(s). 10-2023-0160951, filed on Nov. 20, 2023, the contents of which are all incorporated by reference herein in its entirety.

### BACKGROUND

### 1. Field

The present disclosure relates to a display device.

### 2. Description of the Related Art

With the development of information society, there has been a growing demand for various types of display devices. In order to meet such demand, various display devices, such as a liquid crystal display (LCD), a plasma display panel (PDP), an electro luminescent display (ELD), a vacuum fluorescent display (VFD), an organic light emitting diode (OLED), and the like, have been developed and used.

Among them, a display device using an organic light emitting diode (OLED) has excellent luminance and viewing angle characteristics compared to a liquid crystal display device, and requires no backlight unit, which is advantageous to achieve an ultra-thin profile.

Recently, numerous research has been conducted to obtain the rigidity and structural stability of an ultra-thin large screen display device.

### SUMMARY

It is an objective of the present disclosure to solve the above and other problems.

It is another objective of the present disclosure to achieve structural rigidity of an ultra-thin large screen display device.

It is yet another objective of the present disclosure to achieve structural stability of a display device.

It is yet another objective of the present disclosure to improve the flatness of a frame of a display device.

It is yet another objective of the present disclosure to improve a coupling structure of a display device.

It is yet another objective of the present disclosure to improve the durability and stability of a coupling structure between a material complexed panel and a coupling member.

According to an aspect of the subject matter described in this application, a display device includes: a display panel; a material complexed plate to which the display panel is coupled; and a coupling member coupled to the material complexed plate, wherein the material complexed plate includes: a front skin that defines a front surface of the material complexed plate; a rear skin that defines a rear surface of the material complexed plate, the rear skin facing the front skin; a core positioned between the front skin and the rear skin, the core including fibers; and a coupling hole formed through the front skin, the rear skin, and the core, and the coupling member includes: an outer shell inserted into the coupling hole and coupled to at least one of the front skin or the rear skin; and an inner solid inserted into the outer shell and coupled to the outer shell.

A display device according to the present disclosure has the following effects.

According to at least one of the embodiments of the present disclosure, it is possible to achieve structural rigidity of an ultra-thin large screen display device.

According to at least one of the embodiments of the present disclosure, it is possible to achieve structural stability of a display device.

According to at least one of the embodiments of the present disclosure, it is possible to improve the flatness of a frame of a display device.

According to at least one of the embodiments of the present disclosure, it is possible to improve a coupling structure of a display device.

According to at least one of the embodiments of the present disclosure, it is possible to improve the durability and stability of a coupling structure between a material complexed panel and a coupling member.

Further scope of applicability of the present disclosure will become apparent from the following detailed description. It should be understood, however, that the configurations in the detailed description are given by way of illustration only, since various changes and modifications within the idea and scope of the present disclosure will be apparent to those skilled in the art.

### BRIEF DESCRIPTION OF THE DRAWINGS

FIGS. 1 to 41 illustrate examples of a display device according to embodiments of the present disclosure.

### DETAILED DESCRIPTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In the following description, a suffix such as “module” and “unit” may be used to refer to elements or components. Use of such a suffix herein is merely intended to facilitate description of the specification, and the suffix itself is not intended to give any special meaning or function.

In the present disclosure, that which is well known to one of ordinary skill in the relevant art has generally been omitted for the sake of brevity. The accompanying drawings are used to help easily understand the technical idea of the present disclosure and it should be understood that the idea of the present disclosure is not limited by the accompanying drawings. The idea of the present disclosure should be construed to extend to any alterations, equivalents, and substitutes besides the accompanying drawings.

It will be understood that although the terms “first”, “second”, etc. may be used herein to describe various elements, these elements should not be limited by these terms. These terms are only used to distinguish one element from another.

It will be understood that when a component is referred to as being “connected to” or “coupled to” another component, it may be directly connected to or coupled to another component, or intervening components may be present. In contrast, when a component is referred to as being “directly connected to” or “directly coupled to” another component, there are no intervening components present.

As used herein, a singular representation is intended to include a plural representation unless the context clearly indicates otherwise.

In the following description, when an embodiment is described with reference to a specific figure, reference numeral not shown in the specific figure may be mentioned, if necessary or desired. However, the reference numeral not shown in the specific figure may be mentioned only when the reference numeral is shown in other figures.

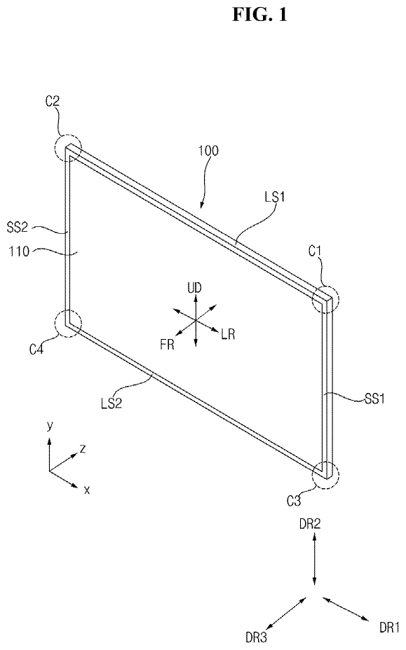

Referring to FIG. 1, a display device 100 may include a display panel 110. The display panel 110 may display an image.

The display device 100 may include a first long side LS1, a second long side LS2 opposite the first long side LS1, a first short side SS1 adjacent to the first long side LS1 and the second long side LS2, and a second short side SS2 opposite the first short side SS1.

For ease of explanation, it is illustrated and described that lengths of the first and second long sides LS1 and LS2 are greater than lengths of the first and second short sides SS1 and SS2, but the lengths of the first and second long sides LS1 and LS2 may be substantially equal to the lengths of the first and second short sides SS1 and SS2.

A direction parallel to the long sides LS1 and LS2 of the display device 100 may be referred to as a first direction DR1 or a left-and-right direction LR. A direction parallel to the short sides SS1 and SS2 of the display device 100 may be referred to as a second direction DR2 or an up-and-down direction UD.

A direction perpendicular to the long sides LS1 and LS2 and the short sides SS1 and SS2 of the display device 100 may be referred to as a third direction DR3 or a front-and-rear direction FR. Here, a direction in which the display panel 110 displays an image may be referred to as a front, and a direction opposite to the front may be referred to as a rear.

Hereinafter, a display panel using an organic light emitting diode (OLED) will be described as an example for the display panel 110, but the display panel 110 applicable to the present disclosure is not limited thereto.

The display panel 110 may define a front surface of the display device 100, and may display an image forward. The display panel 110 may include a plurality of pixels and output an image in accordance with color, brightness, and chroma of each pixel. The display panel 110 may be divided into an active area in which an image is displayed and a de-active area in which no image is displayed. The display panel 110 may generate light corresponding to red, green, or blue color according to a control signal.

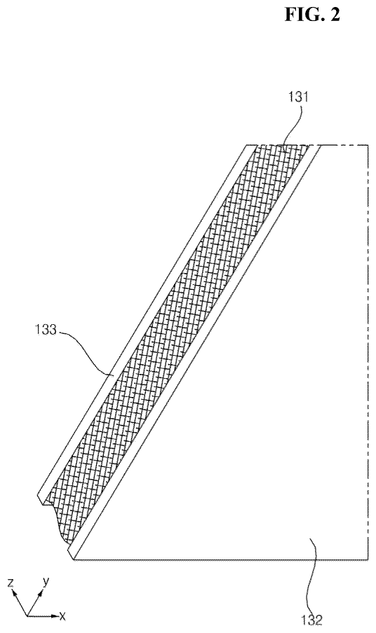

Referring to FIG. 2, a material complexed panel 130 may include a core 131, a front skin 132, and a rear skin 133. The core 131, the front skin 132, and the rear skin 133 may be coupled to each other. The material complexed panel 130 may be referred to as a fiber complexed panel 130, a fiber complexed plate 130, a material complexed plate 130, or a middle frame 130.

The front skin 132 may define a front surface of the material complexed panel 130. The rear skin 133 may define a rear surface of the material complexed panel 130. The front skin 132 and the rear skin 133 may include a metal material.

For example, the front skin 132 and the rear skin 133 may be a galvanized iron sheet. As another example, the front skin 132 and the rear skin 133 may include aluminum (Al).

For example, the thickness of the front skin 132 and the rear skin 133 may be 0.2 to 0.5 mm. As another example, the thickness of the front skin 132 and the rear skin 133 formed of a galvanized iron sheet may be 0.27 mm. As another example, the thickness of the front skin 132 and the rear skin 133 including aluminum (Al) may be 0.5 mm.

The front skin 132 and the rear skin 133 may be disposed opposite each other with respect to the core 131, which will be described below. The core 131 may be positioned between the front skin 132 and the rear skin 133. The core 131 may include fibers. The core 131 may be formed of a composite material. The core 131 may include a main fiber and a binder fiber. The binder fiber may be mixed with the main fiber.

The front skin 132 and/or the rear skin 133 may be coupled to the core 131 by hot-melt processing. A hot-melt sheet may be disposed between the front skin 132 and the core 131, and a hot-melt sheet may be disposed between the rear skin 133 and the core 131. The hot-melt sheet may be a film. For example, the hot-melt sheet may be a film made of EVA, acrylic, polyurethane, or the like having a thickness of 50 μm or more. After the core 131 is placed between the front skin 132 and the rear skin 133 by the hot-melt sheets, roll lamination may be performed at 190° C. for 1 minute or more.

Thus, it is possible to increase bending rigidity and/or torsional rigidity of the display device.

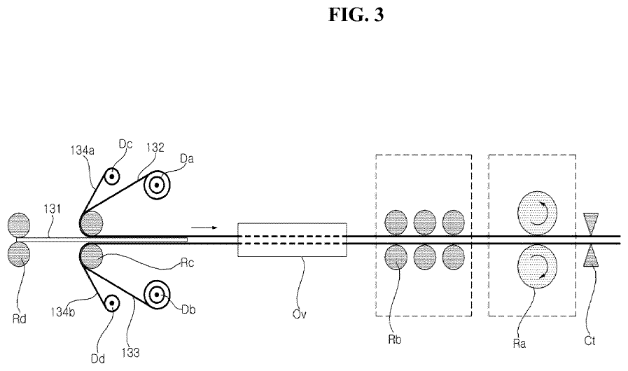

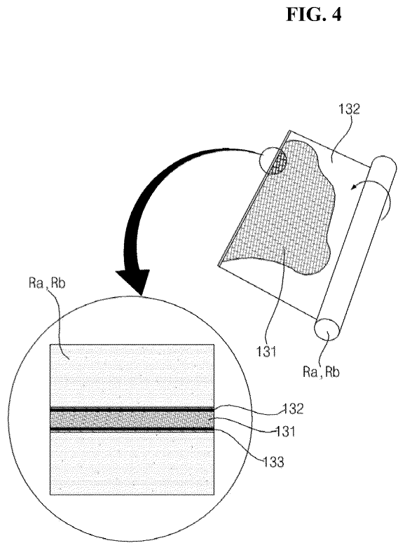

Referring to FIGS. 3 and 4, the material complexed panel 130 may be manufactured by a process of pressing the front skin 132 and the rear skin 133 onto the core 131 using a plurality of rollers. Such a process may be referred to as a Roll-to-Roll (R2R) process.

Referring to FIG. 3, as a pinch roller Ra serving as a drive motor rotates, the front skin 132 may be unwound from a front drum Da, the rear skin 133 may be unwound from a rear drum Db, and the core 131 may be moved by passing through a feeding roller Rd. In addition, a first adhesive 134a for coupling the front skin 132 to the core 131 may be unwound from a first drum Dc. Also, a second adhesive 134b for coupling the rear skin 133 to the core 131 may be unwound from a second drum Db. In this case, the front skin 132, the first adhesive 134a, the core 131, the second adhesive 134b, and the rear skin 133 are stacked in this order, and may be guided toward an oven Ov by a guide roller Rc. The adhesives 134a and 134b may be hot-melt sheets 134a and 134b.

As the first and second adhesives 134a and 134b are melted in the oven Ov, each of the front skin 132 and the rear skin 133 may be coupled to the core 131. For example, the melting point of the first and second adhesives 134a and 134b may be about 150° C., and the ambient temperature of the oven Ov may be about 200° C. For example, the peel-off force of the first and second adhesives 134a and 134b may be about 10 kgf or more.

The front skin 132, the core 131, and the rear skin 133 that have passed through the oven Ov may be guided to a press roller Rb by the rotation of the pinch roller Ra, so as to be pressed by the press roller Rb. Accordingly, the coupling force among the front skin 132, the core 131, and the rear skin 133 may be further increased. The front skin 132, the core 131, and the rear skin 133, which are coupled to each other, may pass through the pinch roller Ra, and then may be cut by a cutter Ct to be manufactured as a material complexed panel 130 of a predetermined size.

Referring to FIG. 4, the press roller Rb or the pinch roller Ra may be brought into contact with an outer surface of each of the front skin 132 and the rear skin 133. When the press roller Rb or the pinch roller Ra rotates, the material complexed panel 130 may be moved in a longitudinal direction of the core 131 (i.e., the left-and-right direction LR). Here, the front skin 132 and the rear skin 133 may be coupled to the core 131 sequentially from one end to the other end in the longitudinal direction of the core 131.

In addition, the front skin 132 and the rear skin 133 of the material complexed panel 130 may be formed flat. That is, as a rear surface of the rear skin 133, which defines a rear surface of the display device 100, is formed flat, it may facilitate an additional operation, such as painting the rear surface of the rear skin 133, attaching a sheet thereto, or the like, for an aesthetically pleasing appearance.

Meanwhile, in addition to the R2R process described above with reference to FIGS. 3 and 4, which is used for making the front skin 132 and the rear skin 133 flat, a process of sequentially stacking the front skin 132, the core 131, and the rear skin 133 followed by coupling the same may be used.

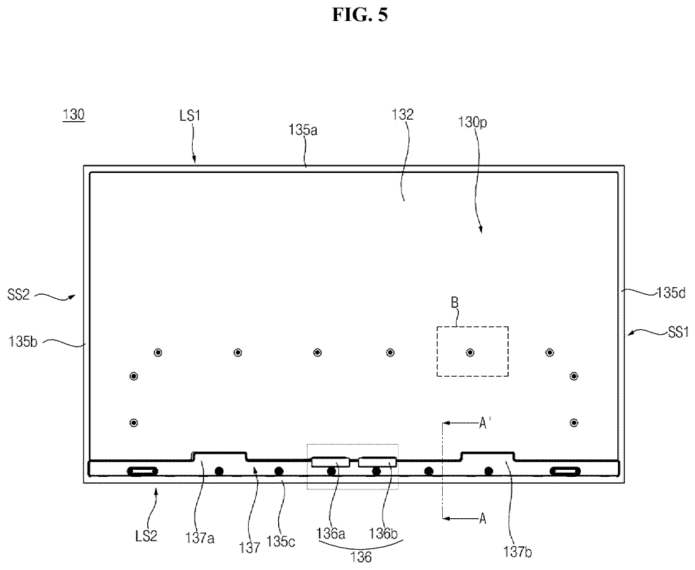

Referring to FIG. 5, the material complexed panel 130 may include a flat part 130P, a receiving part 137, and an outer part 135. The outer part 135 may be formed around the flat part 130P. A first outer part 135a may be formed along an upper side of the flat part 130P, a second outer part 135b may be formed along a left side of the flat part 130P, a third outer part 135c may be formed along a lower side of the flat part 130P, and a fourth outer part 135d may be formed along a right side of the flat part 130P. The outer part 135 may be formed as the flat part 130P is pressed. The outer part 135 may be lowered from the flat part 130P to thereby form a step. The flat part 130P may have a greater thickness than the outer part 135.

A cable hole 136 may be formed through the front skin 132 (see FIG. 2) and the rear skin 133 (see FIG. 2) of the receiving part 137. The cable hole 136 may be formed in the receiving part 137 while being adjacent to the lower side of the flat part 130P. The cable hole 136 may be provided in plurality. A first cable hole 136a and a second cable hole 136b may be positioned adjacent to each other.

The receiving part 137 may be formed between the flat part 130P and the third outer part 135c while being adjacent to the lower side of the flat part 130P. The receiving part 137 may be provided in plurality. A first receiving part 137a may be positioned between the first cable hole 136a and the second short side SS2. A second receiving part 137b may be positioned between the second cable hole 136b and the first short side SS1. The receiving part 137 may be formed as the flat part 130P is pressed. The receiving part 137 may be lowered from the flat part 130P and/or the outer part 135c to thereby form a step.

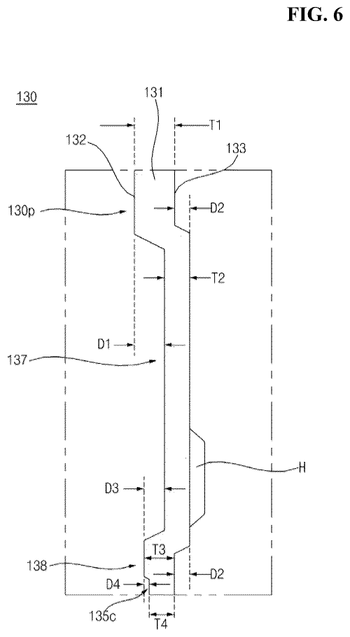

Referring to FIG. 6, the receiving part 137 may be formed as the flat part 130P is pressed. The front skin 132 of the receiving part 137 may form a step D1 descending from the front skin 132 of the flat part 130P. The rear skin 133 of the receiving part 137 may form a step D2 ascending from the rear skin 133 of the flat part 130P. Here, a height of the step D1 descending from the front skin 132 of the flat part 130P to the front skin 132 of the receiving part 137 may be greater than a height of the step D2 ascending from the rear skin 133 of the flat part 130P to the rear skin 133 of the receiving part 137. A thickness T1 of the flat part 130P may be greater than a thickness T2 of the receiving part 137.

As the core 131 of the material complexed panel 130 is pressed in a direction from the front skin 132 to the rear skin 133 of the flat part 130P, the core 131 may absorb an external force. The magnitude of the external force applied to the front skin 132 of the flat part 130P may be greater than the magnitude of the external force applied to the rear skin 133 of the flat part 130P. The core 131 of the material complexed panel 130 may absorb impact as well as achieve rigidity.

A thickness T4 of the third outer part 135c may be greater than the thickness T2 of the receiving part 137. A step D2 ascending from the rear skin 133 of the third outer part 135c to the rear skin 133 of the receiving part 137 may be formed. A height of the step D2 between the rear skin 133 of the third outer part 135c and the rear skin 133 of the receiving part 137 may be equal to the height of the step D2 between the rear skin 133 of the receiving part 137 and the rear skin 133 of the flat part 130P.

A protruding pad 138 may be formed by protruding from the front skin 132 of the third outer part 135c. The front skin 132 of the protruding pad 138 may form a step D4 descending to the front skin 132 of the third outer part 135c. A height of the step D4 formed by the third outer part 135c and the protruding pad 138 may be less than the height of the steps D1 and D2 formed by the flat part 130P and the receiving part 137. A thickness T3 of the protruding pad 138 may be greater than the thickness T4 of the third outer part 135c, may be less than the thickness T1 of the flat part 130P, and may be less than the thickness T2 of the receiving part 137.

A fastening groove H may protrude from the rear skin 133 of the receiving part 137. The fastening groove H may be recessed in the front skin 132 of the receiving part 137 and may protrude from the rear skin 133 of the receiving part 137. A central portion of the fastening groove H may be penetrated.

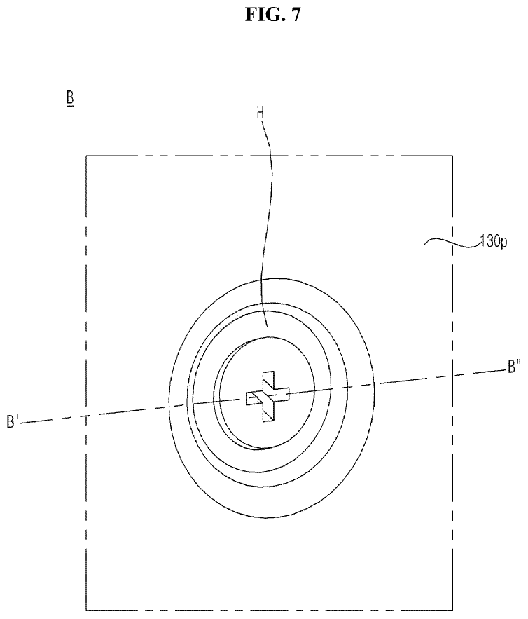

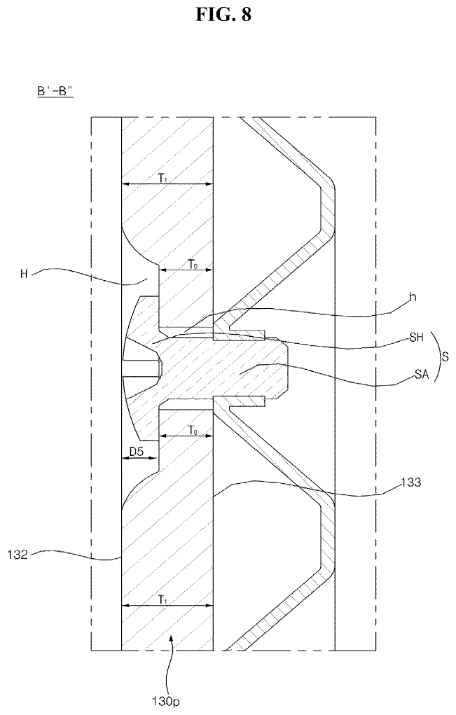

Referring to FIGS. 7 and 8, a fastening groove H may be formed in the flat part 130P. The fastening groove H may be formed as the flat part 130P is pressed. The front skin 132 of the fastening groove H may be formed by being recessed from the front skin 132 of the flat part 130P. The rear skin 133 of the flat part 130P and the rear skin 133 of the fastening groove H may form the same plane. A thickness TO of the fastening groove H may be less than a thickness T1 of the flat part 130P.

The fastening groove H may be provided at its center with a fastening hole h. The fastening hole h may be formed by punching the fastening groove H. The fastening hole h may be formed through the front skin 132 and the rear skin 133 of the fastening groove H. A shaft SA of a fastening member S may have a length greater than the thickness TO of the fastening groove H. The shaft SA of the fastening member S may be inserted into the fastening groove H and protrude to the outside of the rear skin 132 of the fastening groove H through the fastening hole h. A depth D5 of the fastening groove H may be greater than a thickness of a head SH. The head SH of the fastening member S may be hidden in the fastening groove H.

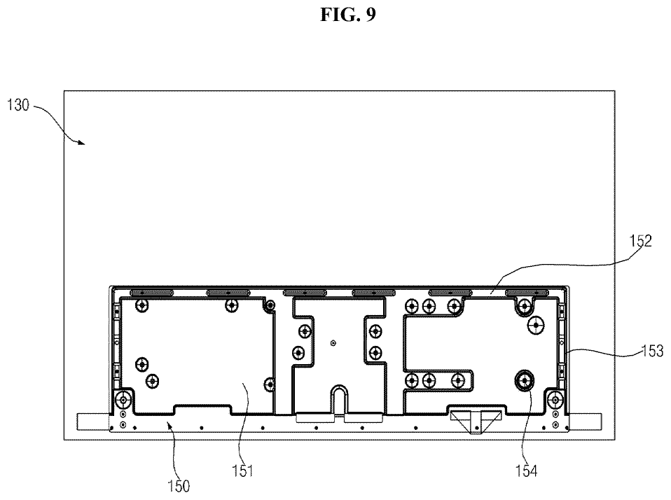

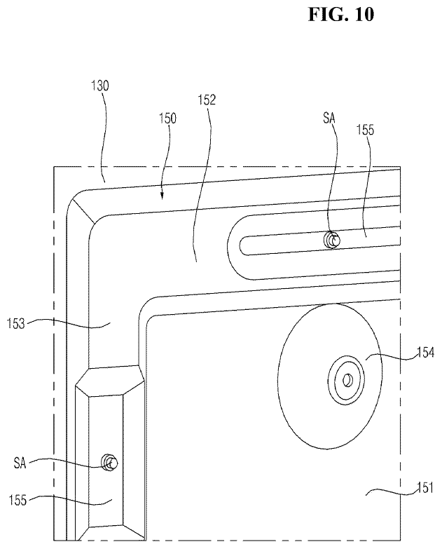

Referring to FIGS. 9 and 10 together with FIG. 8, a PCB plate 150 may be coupled to the rear of the material complexed panel 130. The PCB plate 150 may be fixed to the rear of the material complexed panel 130 by the fastening member S.

The PCB plate 150 may be formed by pressing a plate 151 including a metal. The PCB plate 150 may include a horizontal portion 152, a vertical portion 153, a dome portion 154, and a recessed portion 155. The horizontal portion 152 may protrude from the front to the rear of the PCB plate 151 and may be elongated in a left-and-right direction of the PCB plate 151. The vertical portion 153 may protrude from the front to the rear of the PCB plate 151 and may be elongated in an up-and-down direction of the PCB plate 150. The dome portion 154 may protrude from the front to the rear of the PCB plate 150. The recessed portion 155 may be recessed forward from the rear of the vertical portion 153 and/or the horizontal portion 152.

The shaft SA of the fastening member S may pass through the recessed portion 155 formed in the vertical portion 153 and/or the horizontal portion 152 to couple the material complexed panel 130 with the PCB plate 150. A depth of the recessed portion 155 may be greater than a protruding length of the shaft SA of the fastening member S protruding rearward through the material complexed panel 130.

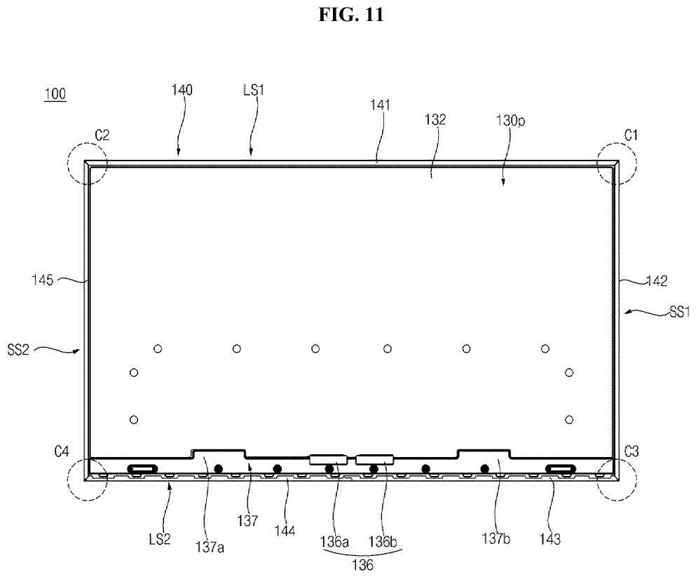

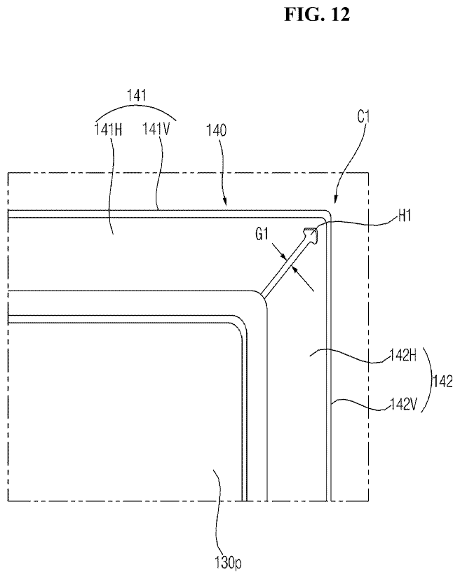

Referring to FIGS. 11 and 12, a side frame 140 may be coupled to the outer part 135 (see FIG. 5) while being adjacent to the flat part 130P. The side frame 140 may include a first part 141, a second part 142, a third part 143, a fourth part 144, and a fifth part 145. The second part 142 may be bent at a first corner C1 from the first part 141.

The first part 141 may include a horizontal portion 141H and a vertical portion 141V. The horizontal portion 141H of the first part 141 may be fixed on the first outer part 135a (see FIG. 5). The second part 142 may include a horizontal portion 142H and a vertical portion 142V. The horizontal portion 142H of the second part 142 may be fixed on the fourth outer part 135d (see FIG. 5).

A gap G1 may be formed between the horizontal portion 141H of the first part 141 and the horizontal portion 142H of the second part 142. The vertical portion 141V of the first part 141 and the vertical portion 142V of the second part 142 may be connected while being bent. A hole H1 connected to the gap G1 may be formed between the horizontal portions 141H and 142H while being adjacent to the vertical portions 141V and 142V. A size of the hole H1 or a diameter of the hole H1 may be greater than a width of the gap G1. The description of the first corner C1 of the side frame 140 is equally applicable to a second corner C2 of the side frame 140.

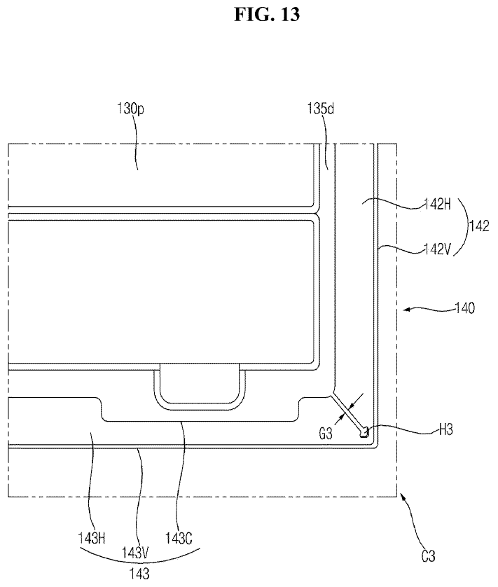

Referring to FIGS. 11 and 13, the side frame 140 may be coupled to the outer part 135 (see FIG. 5) while being adjacent to the flat part 130P. The side frame 140 may include a first part 141, a second part 142, a third part 143, a fourth part 144, and a fifth part 145. The second part 142 may be bent at a third corner C3 from the third part 143.

The third part 143 may include a horizontal portion 143H and a vertical portion 143V. The horizontal portion 143H of the third part 143 may be fixed on the third outer part 135c (see FIG. 5). The second part 142 may include a horizontal portion 142H and a vertical portion 142V. The horizontal portion 142H of the second part 142 may be fixed on the fourth outer part 135d (see FIG. 5).

A gap G3 may be formed between the horizontal portion 143H of the third part 143 and the horizontal portion 142H of the second part 142. The vertical portion 143V of the third part 143 and the vertical portion 142V of the second part 142 may be connected while being bent. A hole H3 connected to the gap G3 may be formed between the horizontal portions 143H and 142H while being adjacent to the vertical portions 143V and 142V. A size of the hole H3 or a diameter of the hole H3 may be greater than a width of the gap G3. The description of the third corner C3 of the side frame 140 is equally applicable to a fourth corner C4 of the side frame 140.

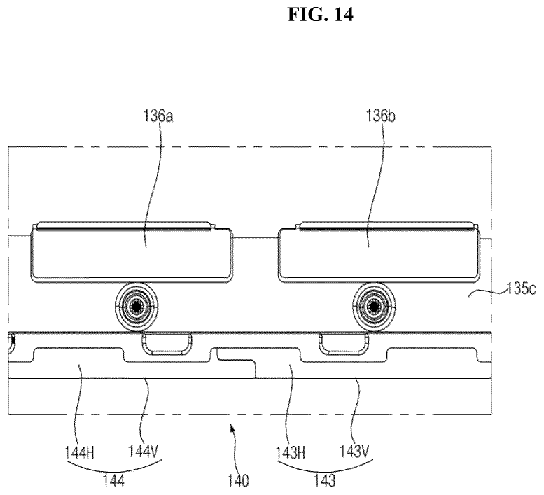

Referring to FIGS. 11 and 14, the third part 143 and the fourth part 144 of the side frame 140 may be positioned or fixed on the third outer part 135c. An end of the third part 143 of the side frame 140 may be coupled to an end of the fourth part 144 of the side frame 140.

A horizontal portion 144H of the fourth part 144 may contact the horizontal portion 143H and the vertical portion 143V of the third part 143. A vertical portion 144V of the fourth part 144 may contact the vertical portion 143V of the third part 143. The vertical portion 143V of the third part 143 may contact the horizontal portion 144H and the vertical portion 144V of the fourth part 144. The end of the third part 143 may be fixed to the end of the fourth part 144. For example, the end of the third part 143 and the end of the fourth part 144 may be fixed by welding.

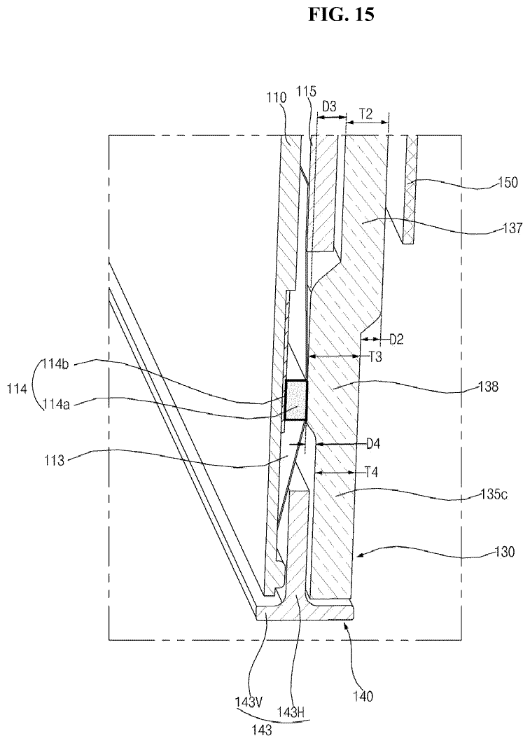

Referring to FIG. 15, the display panel 110 may be coupled or fixed on the side frame 140. The horizontal portion 143H of the side frame 140 may support a rear surface of the display panel 110, and the vertical portion 143V of the side frame 140 may cover a side surface of the display panel 110. For example, the vertical portion 143V of the third part 143 of the side frame 140 may cover a lower side surface of the display panel 110.

The vertical portion 143V may cover a side surface of the material complexed panel 130. For example, the vertical portion 143V of the third part 143 of the side frame 140 may cover a side surface of the third outer part 135c of the material complexed panel 130.

A flexible cable 113 may extend from a lower side of the display panel 110 toward between the display panel 110 and the horizontal portion 143H of the side frame 140. The flexible cable 113 may extend between the rear surface of the display panel 110 and the material complexed panel 130. For example, the flexible cable 113 may be a COF 113.

A source signal substrate 115 may be electrically connected to the flexible cable 113. The source signal substrate 115 may be fixed to one surface of the flexible cable 113. For example, the source signal substrate 115 may be an S-PCB 115. The source signal substrate 115 may be positioned in the receiving part 137 of the material complexed panel 130.

The flexible cable 113 may be positioned between the protruding pad 138 of the material complexed panel 130 and the display panel 110. The flexible cable 113 may contact the protruding pad 138. Heat generated in the source signal substrate 115 and/or the flexible cable 113 may be dissipated through the protruding pad 138.

A heat dissipation pad 114 may be positioned between the flexible cable 113 in contact with the protruding pad 138 and the rear surface of the display panel 110. The heat dissipation pad 114 may include a core 114a and a conductive film 114b. The core 114a of the heat dissipation pad 114 may be formed of an elastic material, and the conductive film 114b may cover the core 114a of the heat dissipation pad 114. Accordingly, the flexible cable 113 may be maintained in contact with the protruding pad 138.

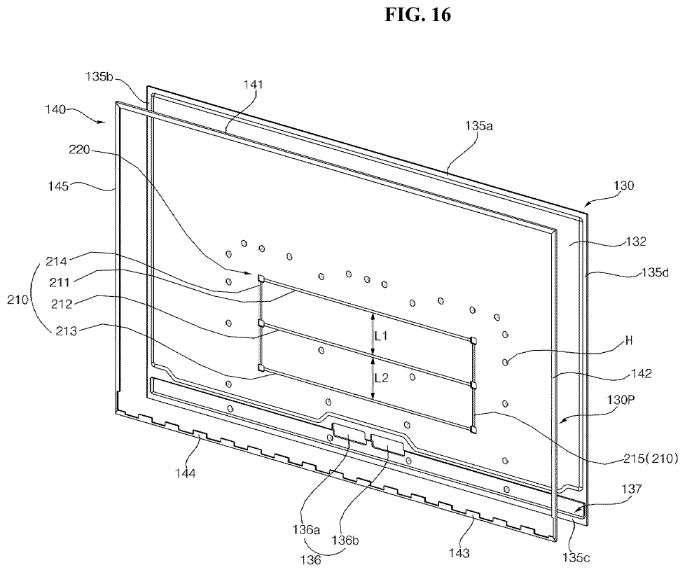

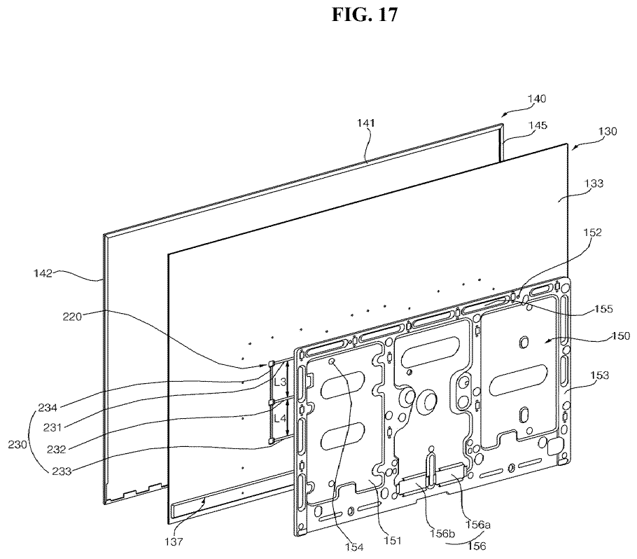

Referring to FIGS. 16 and 17, an inner frame (210, 230) may be formed on the front surface and/or the rear surface of the material complexed panel 130. The inner frame (210, 230) may be referred to as a pressed frame (210, 230) or a rigid line (210, 230). The inner frame (210, 230) may be formed in such a manner that the front skin 132 and/or the rear skin 133 of the material complexed panel 130 are recessed and the core 131 (see FIG. 2) is pressed.

The inner frame (210, 230) may include a front inner line 210, a rear inner line 230, and a node hole 220. The front inner line 210 may be formed as the front skin 132 of the material complexed panel 130 is recessed. The rear inner line 230 may be formed as the rear skin 133 of the material complexed panel 130 is recessed.

The front inner line 210 may include a first front horizontal line 211, a second front horizontal line 212, a third front horizontal line 213, a first front vertical line 214, and a second front vertical line 215. The first front horizontal line 211 may define an upper side of the front inner line 210. The third front horizontal line 213 may define a lower side of the front inner line 210. The second front horizontal line 212 may be positioned between the first front horizontal line 211 and the third front horizontal line 213. The first front vertical line 214 may connect one end of the first front horizontal line 211, one end of the second horizontal line 212, and one end of the third front horizontal line 213. The second front vertical line 215 may connect the other end of the first front horizontal line 211, the other end of the second horizontal line 212, and the other end of the third front horizontal line 213. For example, a first distance L1 between the first front horizontal line 211 and the second front horizontal line 212 may be less than a second distance L2 between the second front horizontal line 212 and the third front horizontal line 213.

The node hole 220 may be formed at a point where the front horizontal line 211, 212, 213 and the front vertical line 214, 215 meet. The node hole 220 may be formed through the front skin 132, the core 131, and the rear skin 133 of the material complexed panel 130.

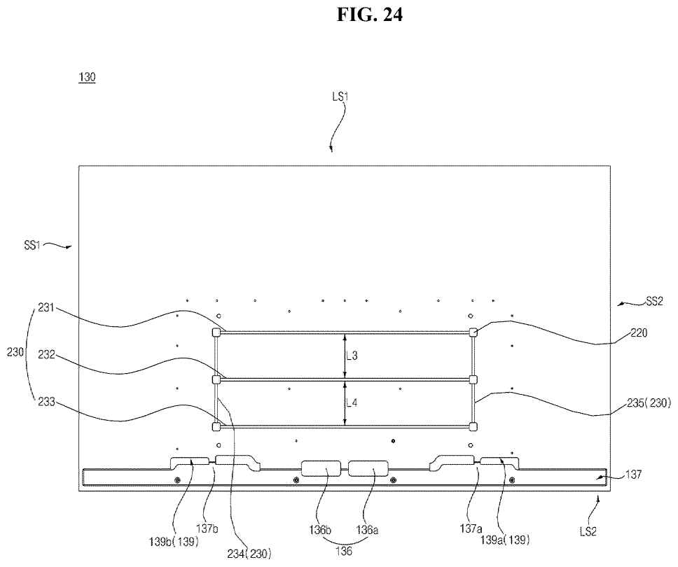

The rear inner line 230 may include a first rear horizontal line 231, a second rear horizontal line 232, a third rear horizontal line 233, a first rear vertical line 234, and a second rear vertical line 235 (see FIG. 24). The first rear horizontal line 231 may define an upper side of the rear inner line 230. The third rear horizontal line 233 may define a lower side of the rear inner line 230. The second rear horizontal line 232 may be positioned between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 (see FIG. 24) may connect the other end of the first rear horizontal line 231, the other end of the second rear horizontal line 232, and the other end of the third rear horizontal line 233. For example, a third distance L3 between the first rear horizontal line 231 and the second rear horizontal line 232 may be less than a fourth distance L4 between the second rear horizontal line 232 and the third rear horizontal line 233.

The node hole 220 may be formed at a point where the rear horizontal line 231, 232, 233 and the rear vertical line 234, 235 meet. The node hole 220 may be formed through the front skin 132, the core 131, and the rear skin 133 of the material complexed panel 130.

A length of the rear inner line 230 may be less than a length of the PCB plate 150. A width of the rear inner line 230 may be less than a width of the PCB plate PCB 150. The PCB plate 150 may cover the rear inner line 230.

Thus, it is possible to increase bending rigidity and/or torsional rigidity of the material complexed panel 130.

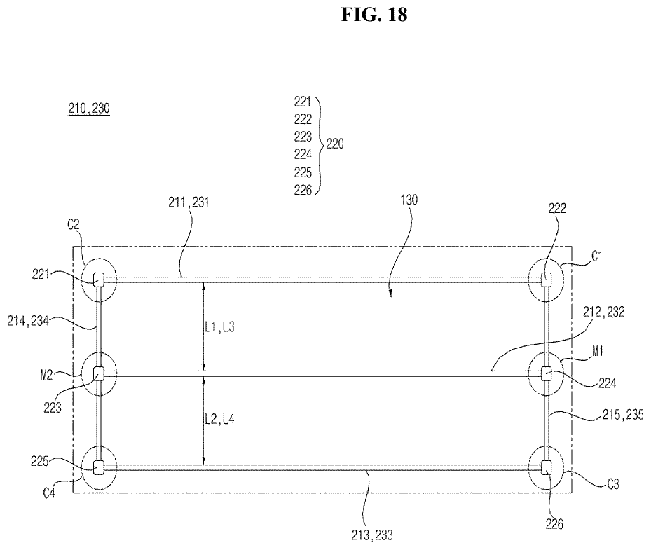

Referring to FIG. 18, a plurality of node holes 220 may be provided. The plurality of node holes 220 may include a first node hole 221, a second node hole 222, a third node hole 223, a fourth node hole 224, a fifth node hole 225, and a sixth node hole 226.

The first node hole 221 may be positioned at a corner C2 defined by the first horizontal line 211, 231 and the first vertical line 214, 234. The first node hole 221 may be formed through the material complexed panel 130 at the conner C2 between the first horizontal line 211, 231 and the first vertical line 214, 234.

The second node hole 222 may be positioned at a conner C1 defined by the first horizontal line 211, 231 and the second vertical line 215, 235. The second node hole 222 may be formed through the material complexed panel 130 at the corner C1 between the first horizontal line 211, 231 and the second vertical line 215, 235.

The third node hole 223 may be positioned at a node M2 defined by the second horizontal line 212, 232 and the first vertical line 214, 234. The third node hole 223 may be formed through the material complexed panel 130 at the node M2 between the second horizontal line 212, 232 and the first vertical line 214, 234.

The fourth node hole 224 may be positioned at a node M1 defined by the second horizontal line 212, 232 and the second vertical line 215, 235. The fourth node hole 224 may be formed through the material complexed panel 130 at the node M1 between the second horizontal line 212, 232 and the second vertical line 215, 235.

The fifth node hole 225 may be positioned at a corner C4 defined by the third horizontal line 213, 233 and the first vertical line 214, 234. The fifth node hole 225 may be formed through the material complexed panel 130 at the corner C4 between the third horizontal line 213, 233 and the first vertical line 214, 234.

The sixth node hole 226 may be positioned at a corner C3 defined by the third horizontal line 213, 233 and the second vertical line 215, 235. The sixth node hole 226 may be formed through the material complexed panel 130 at the corner C3 between the third horizontal line 213, 233 and the second vertical line 215, 235.

Thus, it is possible to not only increase bending rigidity and/or torsional rigidity of the material complexed panel 130, but also to improve flatness of the display panel 110 coupled to the material complexed panel 130.

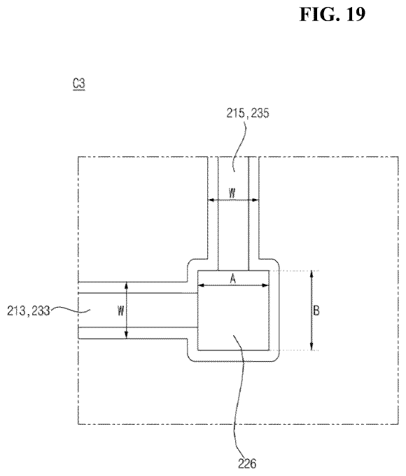

Referring to FIG. 19, the sixth node hole 226 may have a size greater than a width of the third horizontal line 213, 233 and/or the second vertical line 215, 235. For example, when the sixth node hole 226 is of a quadrangular shape, a width A, B of the node hole 226 may be greater than a width W of the third horizontal line 213, 233 and/or the second vertical line 215, 235. As another example, when the sixth node hole 226 is of a circular shape, the sixth node hole 226 may have a diameter greater than the width of the third horizontal line 213, 233 and/or the second vertical line 215, 235. The description of the sixth node hole 226 is equally applicable to the first node hole 221, the second node hole 222, and/or the fifth node hole 225.

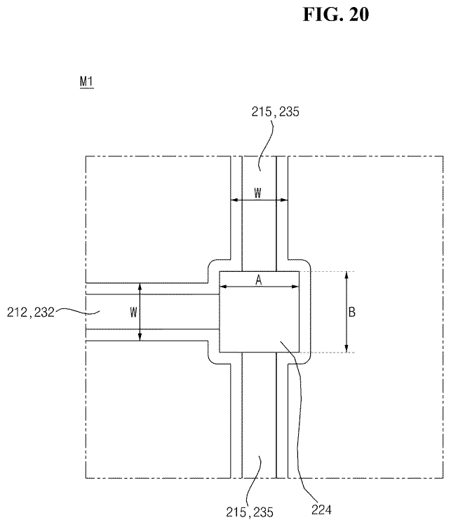

Referring to FIG. 20, the fourth node hole 224 may have a size greater than a width of the second horizontal line 212, 232 and/or the second vertical line 215, 235. For example, when the fourth node hole 224 is of a quadrangular shape, a width A, B of the fourth node hole 224 may be greater than a width W of the second horizontal line 212, 232 and/or the second vertical line 215, 235. As another example, when the fourth node hole 224 is of a circular shape, the fourth node hole 224 may have a diameter greater than the width of the second horizontal line 212, 232 and/or the second vertical line 215, 235. The description of the fourth node hole 224 is equally applicable to the third node hole 223.

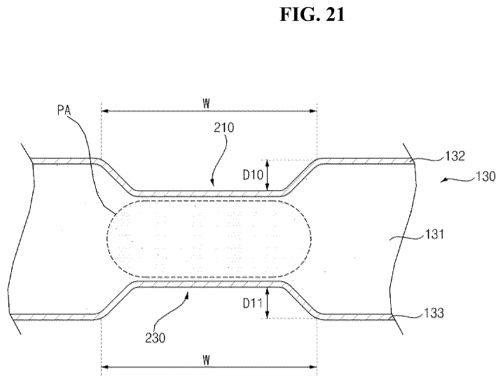

Referring to FIG. 21, the front skin 132 may be recessed as the core 131 is pressed, so that the front inner line 210 may be formed on the material complexed panel 130. The rear skin 133 may be recessed as the core 131 is pressed, so that the rear inner line 230 may be formed on the material complexed panel 130.

The front inner line 210 and the rear inner line 230 may be symmetric with respect to the core 131. For example, a width W of the front inner line 210 may be substantially equal to a width W of the rear inner line 230. As another example, a depth D10 of the front inner line 210 may be substantially equal to a depth D11 of the rear inner line 230.

A pressed area PA caused by the core 131 being pressed may be formed between the front inner line 210 and the rear inner line 230. The density of the core 131 in the pressed area PA may be greater than the density of the core 131 in a non-pressed area.

Thus, it is possible to increase bending rigidity and/or torsional rigidity of the material complexed panel 130.

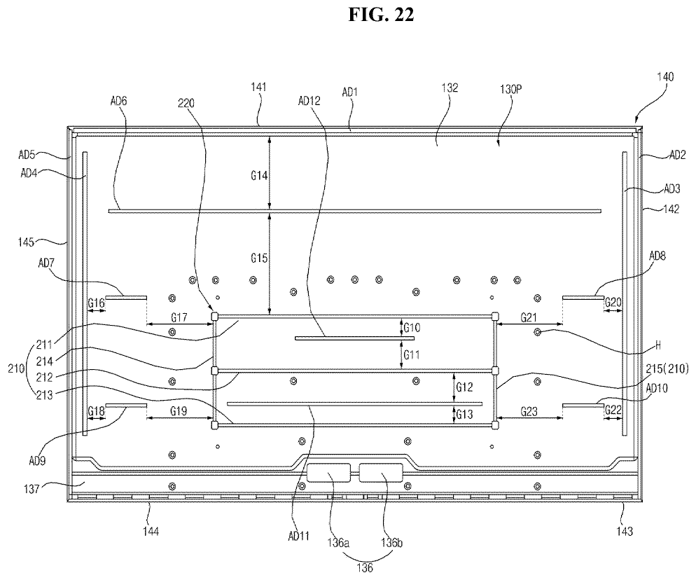

Referring to FIG. 22, an adhesive member AD may be disposed on the flat part 130P of the material complexed panel 130. The adhesive member AD may be attached to the front skin 132 of the material complexed panel 130. The adhesive member AD may be provided in plurality.

A first adhesive member AD1 may be fixed to the first part 141 of the side frame 140. The first adhesive member AD1 may be elongated along a longitudinal direction of the first part 141 of the side frame 140. A second adhesive member AD2 may be elongated along a longitudinal direction of the second part 142 of the side frame 140, and may be fixed to the second part 142. A third adhesive member AD3 may be elongated along the second part 142 of the side frame 140, may be parallel to the second part 142, and may be fixed to the flat part 130P while being spaced apart from the first adhesive member AD1.

A fifth adhesive member AD5 may be elongated along a longitudinal direction of the fifth part 145 of the side frame 140, and may be fixed to the fifth part 145. A fourth adhesive member AD4 may be elongated along the fifth part 145 of the side frame 140, may be parallel to the fifth part 145, and may be fixed to the flat part 130P while being spaced apart from the fifth adhesive member AD5.

A sixth adhesive member AD6 may be elongated along the longitudinal direction of the first part 141 of the side frame 140, and may be fixed to the flat part 130P while being spaced apart from the first adhesive member AD1. A fourteenth distance G14 from the first part 141 of the side frame 140 to the sixth adhesive member AD6 may be less than a fifteenth distance G15 from the sixth adhesive member AD6 to the first front horizontal inner line 211.

A seventh adhesive member AD7 may extend along a longitudinal direction of the sixth adhesive member AD6, and may be fixed to the flat part 130P between the first front vertical line 214 and the fourth adhesive member AD4. The seventh adhesive member AD7 may be positioned between the sixth adhesive member AD6 and a ninth adhesive member AD9. A sixteenth distance G16 from the fourth adhesive member AD4 to one end of the seventh adhesive member AD7 may be less than a seventeenth distance G17 from the first front vertical line 214 to the other end of the seventh adhesive member AD7.

The ninth adhesive member AD9 may extend along the longitudinal direction of the sixth adhesive member AD6, and may be fixed to the flat part 130P between the first front vertical line 214 and the fourth adhesive member AD4. The ninth adhesive member AD9 may be positioned between the seventh adhesive member AD7 and the receiving part 137. An eighteenth distance G18 from the fourth adhesive member AD4 to one end of the ninth adhesive member AD9 may be less than a nineteenth distance G19 from the first front vertical line 214 to the other end of the ninth adhesive member AD9.

An eighth adhesive member AD8 may extend along the longitudinal direction of the sixth adhesive member AD6, and may be fixed to the flat part 130P between the second front vertical line 215 and the third adhesive member AD3. The eighth adhesive member AD8 may be positioned between the sixth adhesive member AD6 and the receiving part 137. A twentieth distance G20 from the third adhesive member AD3 to one end of the eighth adhesive member AD8 may be less than a twenty-first distance G21 from the second front vertical line 215 to the other end of the eighth adhesive member AD8.

A tenth adhesive member AD10 may extend along the longitudinal direction of the sixth adhesive member AD6, and may be fixed to the flat part 130P between the second front vertical line 215 and the third adhesive member AD3. The tenth adhesive member AD10 may be positioned between the eighth adhesive member AD8 and the receiving part 137. A twenty-second distance G22 from the third adhesive member AD3 to one end of the tenth adhesive member AD10 may be less than a twenty-third distance G23 from the second front vertical line 215 to the other end of the tenth adhesive member AD10.

An eleventh adhesive member AD11 may be elongated along a longitudinal direction of the second front horizontal line 212, and may be fixed to the flat part 130P between the second front horizontal line 212 and the third front horizontal line 213. A twelfth adhesive member AD12 may be elongated along the longitudinal direction of the second front horizontal line 212, and may be fixed to the flat part 130P between the first front horizontal line 211 and the second front horizontal line 212. A length of the twelfth adhesive member AD12 may be less than a length of the eleventh adhesive member AD11.

A tenth distance G10 between the first front horizontal line 211 and the twelfth adhesive member AD12 may be less than an eleventh distance G11 between the twelfth adhesive member AD12 and the second front horizontal line 212. For example, the tenth distance G10 may be 40 mm or more. For example, a distance between one end of the twelfth adhesive member AD12 and the first vertical front line 214 may be 20 mm or more. As another example, a distance between the other end of the twelfth adhesive member AD12 and the second vertical front line 215 may be 20 mm or more.

A twelfth distance G12 between the second front horizontal line 212 and the eleventh adhesive member AD11 may be greater than a thirteenth distance G13 between the eleventh adhesive member AD11 and the third front horizontal line 213. For example, the thirteenth distance G13 may be 40 mm or more.

The display panel 110 may be coupled or fixed to the material complexed panel 130 by the adhesive member AD. Accordingly, the display panel 110 may be fixed to the material complexed panel 130 in a flat manner.

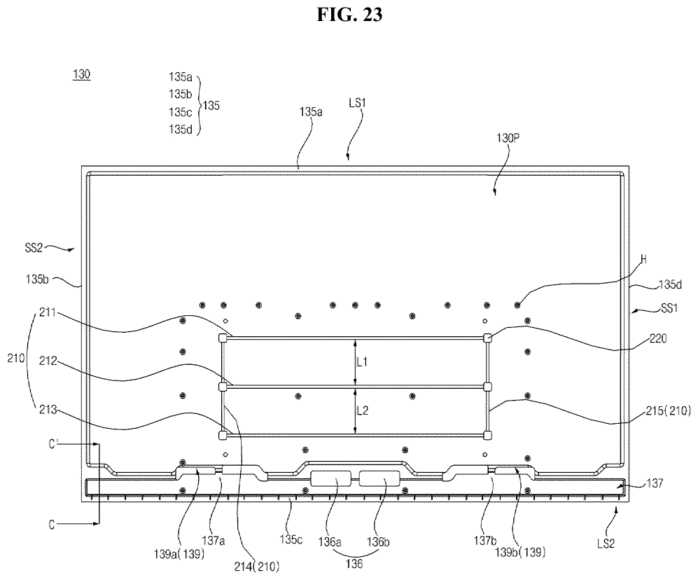

Referring to FIGS. 23 and 24, the material complexed panel 130 may include a flat part 130P, a receiving part 137, and an outer part 135. The outer part 135 may be formed around the flat part 130P, and may define an edge of the material complexed panel 130. A first outer part 135a may be formed along an upper side of the flat part 130P, a second outer part 135b may be formed along a left side of the flat part 130P, a third outer part 135c may be formed along a lower side of the flat part 130P, and a fourth outer part 135d may be formed along a right side of the flat part 130P. The outer part 135 may be formed as the flat part 130P is pressed. The outer part 135 may be lowered from the flat part 130P to thereby form a step. The flat part 130P may have a greater thickness than the outer part 135. The lower side of the flat part 130P may form a line with a curve.

The receiving part 137 may be formed on the third outer part 135c while being adjacent to the lower side of the flat part 130P. The receiving part 137 may be provided in plurality. A first receiving part 137a may be positioned between a first cable hole 136a and the second short side SS2. A second receiving part 137b may be positioned between a second cable hole 136b and the first short side SS1. The first receiving part 137a may be connected to the second receiving part 137b. The receiving part 137 may be formed as the third outer part 135c is pressed from the front to the rear. The receiving part 137 may form a step descending from a front surface of the third outer part 135c.

A cable hole 136 may be formed through the front skin 132 (see FIG. 2) and the rear skin 133 (see FIG. 2) of the receiving part 137. The cable hole 136 may be formed in the receiving part 137 and/or the third outer part 135c while being adjacent to the lower side of the flat part 130P. The cable hole 136 may be provided in plurality. The first cable hole 136a and the second cable hole 136b may be positioned adjacent to each other.

An inner frame (210, 230) may be formed on the front surface and/or the rear surface of the material complexed panel 130. The inner frame (210, 230) may be referred to as a pressed frame (210, 230) or a rigid line (210, 230). The inner frame (210, 230) may be formed in such a manner that the front skin 132 and/or the rear skin 133 of the material complexed panel 130 are recessed and the core 131 (see FIG. 2) is pressed.

The inner frame (210, 230) may include a front inner line 210, a rear inner line 230, and a node hole 220. The front inner line 210 may be formed as the front skin 132 of the material complexed panel 130 is recessed. The rear inner line 230 may be formed as the rear skin 133 of the material complexed panel 130 is recessed.

The front inner line 210 may include a first front horizontal line 211, a second front horizontal line 212, a third front horizontal line 213, a first front vertical line 214, and a second front vertical line 215. The first front horizontal line 211 may define an upper side of the front inner line 210. The third front horizontal line 213 may define a lower side of the front inner line 210. The second front horizontal line 212 may be positioned between the first front horizontal line 211 and the third front horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213. For example, a first distance L1 between the first front horizontal line 211 and the second front horizontal line 212 may be less than a second distance L2 between the second front horizontal line 212 and the third front horizontal line 213.

The node hole 220 may be formed at a point where the front horizontal line 211, 212, 213 and the front vertical line 214, 215 meet. The node hole 220 may be formed through the front skin 132, the core 131, and the rear skin 133 of the material complexed panel 130.

The rear inner line 230 may include a first rear horizontal line 231, a second rear horizontal line 232, a third rear horizontal line 233, a first rear vertical line 234, and a second rear vertical line 235. The first rear horizontal line 231 may define an upper side of the rear inner line 230. The third rear horizontal line 233 may define a lower side of the rear inner line 230. The second rear horizontal line 232 may be positioned between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 may connect the other end of the first rear horizontal line 231, the other end of the second rear horizontal line 232, and the other end of the third rear horizontal line 233. For example, a third distance L3 between the first rear horizontal line 231 and the second rear horizontal line 232 may be less than a fourth distance L4 between the second rear horizontal line 232 and the third rear horizontal line 233.

The node hole 220 may be formed at a point where the rear horizontal line 231, 232, 233 and the rear vertical line 234, 235 meet. The node hole 220 may be formed through the front skin 132, the core 131, and the rear skin 133 of the material complexed panel 130.

The receiving part 137 may be formed as the third outer part 135c is pressed from the front to the rear. The receiving part 137 may form a step ascending from a rear surface of the third outer part 135c.

A cut-out portion 139 may be formed on at least a portion of the curved line defined along the lower side of the flat part 130P. The cut-out portion 39 may be provided in plurality. A first cut-out portion 139a may be aligned to the first receiving part 137a, and a second cut-out portion 139b may be aligned to the second receiving part 137b. The cut-out portion 139 may be formed on a line defining a step between a front surface of the flat part 130P and the third outer part 135c. The cut-out portion 139 may be formed on a line defining a step between the third outer part 135c and the receiving part 137.

Thus, it is possible to not only increase bending rigidity and/or torsional rigidity of the material complexed panel 130, but also to improve flatness of the material complexed panel 130.

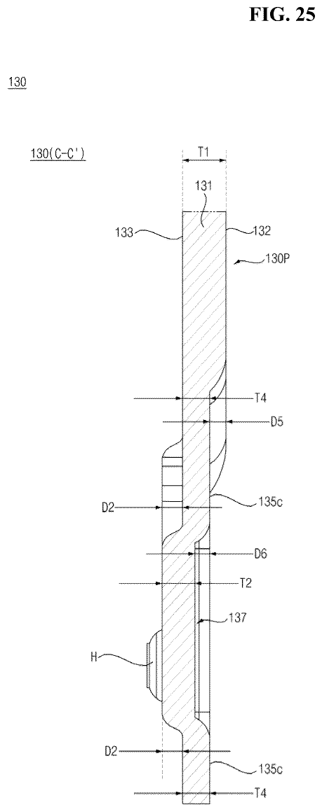

Referring to FIG. 25, the third outer part 135c may be formed as the flat part 130P is pressed. The front skin 132 of the third outer part 135c may form a step D5 descending from the front skin 132 of the flat part 130P.

The receiving part 137 may be formed as the third outer part 135c is pressed. The front skin 132 of the receiving part 137 may form a step D6 descending from the front skin 132 of the third outer part 135c.

The rear skin 133 of the receiving part 137 may form a step D2 ascending from the rear skin 133 of the third outer part 135c. For example, a height of the step D6 descending from the front skin 132 of the third outer part 135c to the front skin 132 of the receiving part 137 may be less than a height of the step D2 ascending from the rear skin 133 of the third outer part 135c to the rear skin 133 of the receiving part 137. A thickness T1 of the flat part 130P may be greater than a thickness T2 of the receiving part 137. A thickness T4 of the third outer part 135c may be less than the thickness T1 of the flat part 130P. The thickness T2 of the receiving part 137 may be greater than the thickness T4 of the third outer part 135c.

As the core 131 of the material complexed panel 130 is pressed in a direction from the front skin 132 to the rear skin 133 of the flat part 130P, the core 131 may absorb an external force. The magnitude of the external force applied to the front skin 132 of the flat part 130P may be greater than the magnitude of the external force applied to the rear skin 133 of the flat part 130P. The core 131 of the material complexed panel 130 may absorb impact as well as achieve rigidity.

A fastening groove H may protrude from the rear skin 133 of the receiving part 137. The fastening groove H may be recessed in the front skin 132 of the receiving part 137 and may protrude from the rear skin 133 of the receiving part 137. A central portion of the fastening groove H may be penetrated.

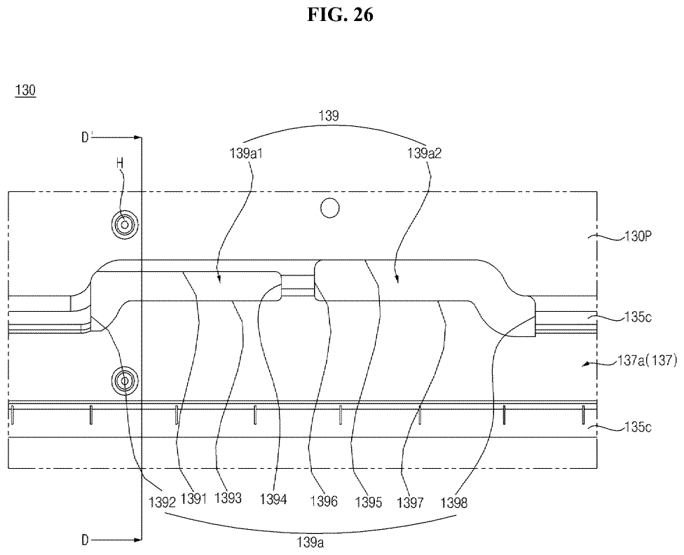

Referring to FIG. 26, the first cut-out portion 139a may include a first slit 139a1 and a second slit 139a2. The first slit 139al and/or the second slit 139a2 may be elongated in a longitudinal direction of the receiving part 137. The first slit 139al may be formed at a boundary of the flat part 130P, a boundary of the third outer part 135c, and/or a boundary of the first receiving part 137a. The second slit 139a2 may be formed at the boundary of the flat part 130P, the boundary of the third outer part 135c, and/or the boundary of the first receiving part 137a while being adjacent to the first slit 139a1.

The first slit 139al may include an upper side 1391, a left side 1392, a right side 1394, and a lower side 1393. The upper side 1391 may be formed in a step region formed at a lower side boundary of the flat part 130P. The lower side 1393 may be formed in the first receiving part 137a while being adjacent to an upper side of the first receiving part 137a. The left side 1392 may connect a left end of the upper side 1391 and a left end of the lower side 1393, and may be formed in a step region at the lower side of the flat part 130P, the third outer part 135c, and/or the first receiving part 137a. The right side 1394 may be formed in a step region formed at the lower side boundary of the flat part 130P, the third outer part 135c, and/or the first receiving part 137a. For example, a length of the left side 1392 may be greater than a length of the right side 1394, the upper side 1391 may define a straight line, and the lower side 1393 may include a straight line and a curved line.

The second slit 139a2 may include an upper side 1395, a left side 1396, a right side 1398, and a lower side 1397. The upper side 1395 may be formed at the lower side boundary of the flat part 130P. The lower side 1397 may be formed in the first receiving part 137a while being adjacent to the upper side of the first receiving part 137a. The left side 1396 may connect a left end of the upper side 1395 and a left end of the lower side 1397, and may be formed in a step region at the lower side of the flat part 130P, the third outer part 135c, and/or the first receiving part 137a. The right side 1398 may be formed in a step region formed at the lower side boundary of the flat part 130P, the third outer part 135c, and/or the first receiving part 137a. For example, a length of the left side 1396 may be substantially equal to a length of the right side 1398, the upper side 1395 may include a straight line and a curved line, and the lower side 1397 may include a straight line and a curved line. The upper side 1395 and the lower side 1397 may be parallel to each other.

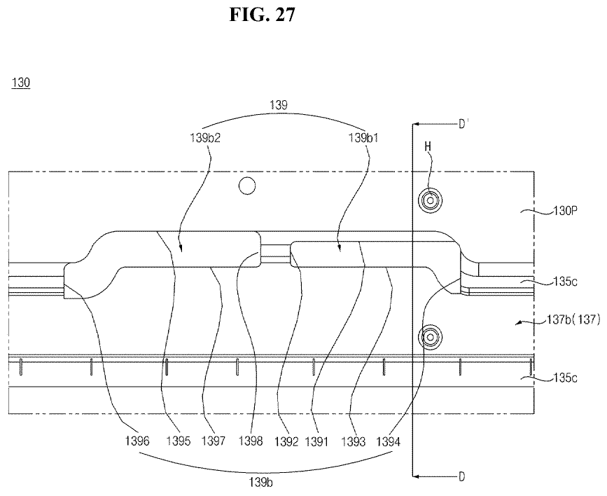

Referring to FIG. 27, the second cut-out portion 139b may include a first slit 139b1 and a second slit 139b2. The first slit 139b1 and/or the second slit 139b2 may be elongated in the longitudinal direction of the receiving part 137. The first slit 139b1 may be formed at a boundary of the flat part 130P, a boundary of the third outer part 135c, and/or a boundary of the second receiving part 137b. The second slit 139b2 may be formed at the boundary of the flat part 130P, the boundary of the third outer part 135c, and/or the boundary of the second receiving part 137b while being adjacent to the first slit 139b1.

The first slit 139b1 may include an upper side 1391, a left side 1392, a right side 1394, and a lower side 1393. The upper side 1391 may be formed in a step region formed at a lower side boundary of the flat part 130P. The lower side 1393 may be formed in the second receiving part 137b while being adjacent to an upper side of the second receiving part 137b. The left side 1392 may connect a left end of the upper side 1391 and a left end of the lower side 1393, and may be formed in a step region at the lower side of the flat part 130P, the third outer part 135c, and/or the second receiving part 137b. The right side 1394 may be formed in a step region formed at the lower side boundary of the flat part 130P, the third outer part 135c, and/or the second receiving part 137b. For example, a length of the left side 1392 may be greater than a length of the right side 1394, the upper side 1391 may define a straight line, and the lower side 1393 may include a straight line and a curved line.

The second slit 139b2 may include an upper side 1395, a left side 1396, a right side 1398, and a lower side 1397. The upper side 1395 may be formed at the lower side boundary of the flat part 130P. The lower side 1397 may be formed in the second receiving part 137b while being adjacent to the upper side of the second receiving part 137b. The left side 1396 may connect a left end of the upper side 1395 and a left end of the lower side 1397, and may be formed in a step region at the lower side of the flat part 130P, the third outer part 135c, and/or the second receiving part 137b. The right side 1398 may be formed in a step region formed at the lower side boundary of the flat part 130P, the third outer part 135c, and/or the second receiving part 137b. For example, a length of the left side 1396 may be substantially equal to a length of the right side 1398, the upper side 1395 may include a straight line and a curved line, and the lower side 1397 may include a straight line and a curved line. The upper side 1395 and the lower side 1397 may be parallel to each other.

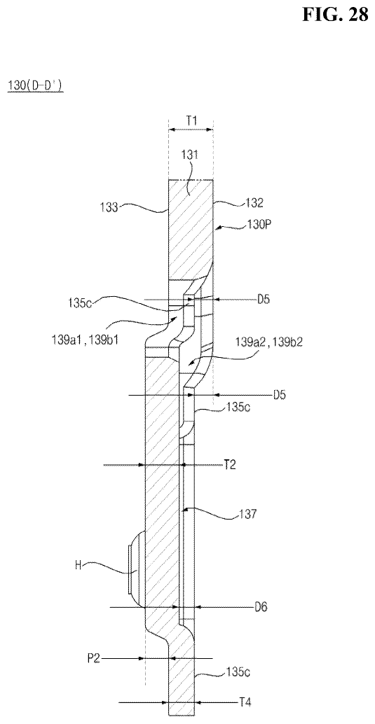

Referring to FIG. 28, the third outer part 135c may be formed as the flat part 130P is pressed. The front skin 132 of the third outer part 135c may form a step D5 descending from the front skin 132 of the flat part 130P.

The receiving part 137 may be formed as the third outer part 135c is pressed. The front skin 132 of the receiving part 137 may form a step D6 descending from the front skin 132 of the third outer part 135c.

The rear skin 133 of the receiving part 137 may form a step D2 ascending from the rear skin 133 of the third outer part 135c. For example, a height of the step D6 descending from the front skin 132 of the third outer part 135c to the front skin 132 of the receiving part 137 may be less than a height of the step D2 ascending from the rear skin 133 of the third outer part 135c to the rear skin 133 of the receiving part 137. A thickness T1 of the flat part 130P may be greater than a thickness T2 of the receiving part 137. A thickness T4 of the third outer part 135c may be less than the thickness T1 of the flat part 130P. The thickness T2 of the receiving part 137 may be greater than the thickness T4 of the third outer part 135c.

As the core 131 of the material complexed panel 130 is pressed in a direction from the front skin 132 to the rear skin 133 of the flat part 130P, the core 131 may absorb an external force. The magnitude of the external force applied to the front skin 132 of the flat part 130P may be greater than the magnitude of the external force applied to the rear skin 133 of the flat part 130P. The core 131 of the material complexed panel 130 may absorb impact as well as achieve rigidity.

A fastening groove H may protrude from the rear skin 133 of the receiving part 137. The fastening groove H may be recessed in the front skin 132 of the receiving part 137 and may protrude from the rear skin 133 of the receiving part 137. A central portion of the fastening groove H may be penetrated.

The first slit 139a1, 139b1 may be formed through the front skin 132, the core 131, and/or the rear skin 133. The second slit 139a2, 139b2 may be formed through the front skin 132, the core 131, and/or the rear skin 133.

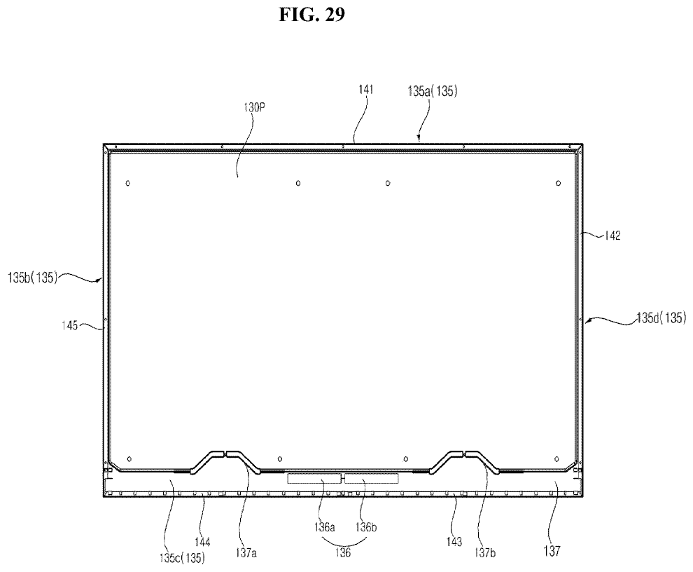

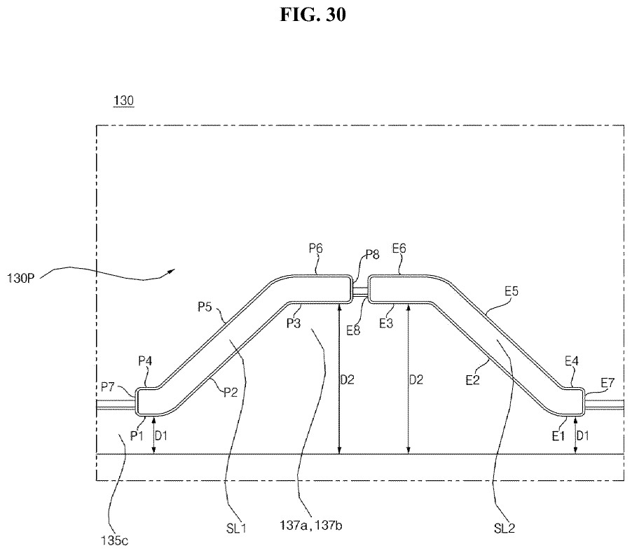

Referring to FIGS. 29 and 30, the outer part 135 may be formed around the flat part 130P. The outer part 135 may form a step descending from the flat part 130P. The outer part 135 may be formed as the front skin 132 is recessed by the core 131 (see FIG. 2) being pressed. Alternatively, the outer part 135 may be formed as the front skin 132 is recessed and the rear skin 133 protrudes by the core 131 being pressed.

The third outer part 135c may be formed adjacent to the lower side of the flat part 130P. The third outer part 135c may be formed at a lower end of the flat part 130P while forming a step descending from the flat part 130P.

The receiving part 137, 137a, 137b may be formed at the third outer part 135c. The receiving part 137, 137a, 137b may be formed as the flat part 130P is pressed. The receiving part 137, 137a, 137b may form a step descending from the flat part 130P. For example, the receiving part 137, 137a, 137b may form the same plane as the third outer part 135c. As another example, the receiving part 137, 137a, 137b may be formed as the third outer part 135c is pressed.

A barrier slit (SL1, SL2) may be positioned at a boundary between the flat part 130P and the receiving part 137a, 137b. The barrier slit (SL1, SL2) may be referred to as a barrier (SL1, SL2). The barrier slit (SL1, SL2) may be referred to as a cut-out portion (SL1, SL2). The barrier slit (SL1, SL2) may be referred to as a barrier cut-out (SL1, SL2).

The barrier slit (SL1, SL2) may be formed on the inclined surface of a step descending from the flat part 130P to the receiving part 137a, 137b. The barrier slit (SL1, SL2) may be formed as a portion of the flat part 130P and a portion of the receiving part 137a, 137b are cut out. The barrier slit (SL1, SL2) may be provided in plurality. The plurality of barrier slits (SL1, SL2) may include a first slit SL1 and a second slit SL2.

The first slit SL1 may include a first part P1, a second part P2, a third part P3, a fourth part P4, a fifth part P5, a sixth part P6, a seventh part P7, and an eighth part P8. The first part P1, the second part P2, and the third part P3 may define a lower side of the first slit SL1. The fourth part P4, the fifth part P5, and the sixth part P6 may define an upper side of the first slit SL1. The upper side of the first slit SL1 may be parallel to the lower side of the first slit SL1. The seventh part P7 may connect one end of the upper side and one end of the lower side of the first slit SL1, and the eighth part P8 may connect the other end of the upper side and the other end of the lower side of the first slit SL1. The seventh part P7 may be parallel to the eighth part P8.

The first part P1 may be parallel to the third part P3. The third part P3 may be spaced apart from the first part P1. The second part P2 may connect the first part P1 and the third part P3. The fourth part P4 may be parallel to the sixth part P6. The sixth part P6 may be spaced apart from the fourth part P4. The fifth part P5 may connect the fourth part P4 and the sixth part P6.

The fourth part P4, the fifth part P5, and the sixth part P6 may define one edge of the flat part 130P. The first part P1, the second part P2, and the third part P3 may define one edge of the receiving part 137a, 137b. The seventh part P7 and the eighth part P8 may define one edge of a step connecting the receiving part 137a, 137b and the flat part 130P.

A second distance D2 from the lower side of the receiving part 137a, 137b to the third part P3 may be greater than a first distance D1 from the lower side of the receiving part 137a, 137b to the first part P1.

The second slit SL2 may include a first part E1, a second part E2, a third part E3, a fourth part E4, a fifth part E5, a sixth part E6, a seventh part E7, and an eighth part E8. The first part E1, the second part E2, and the third part E3 may define a lower side of the second slit SL2. The fourth part E4, the fifth part E5, and the sixth part E6 may define an upper side of the second slit SL2. The upper side of the second slit SL2 may be parallel to the lower side of the second slit SL2. The seventh part E7 may connect one end of the upper side and one end of the lower side of the second slit SL2, and the eighth part E8 may connect the other end of the upper side and the other end of the lower side of the second slit SL2. The seventh part E7 may be parallel to the eighth part E8.

The first part E1 may be parallel to the third part E3. The third part E3 may be spaced apart from the first part E1. The second part E2 may connect the first part E1 and the third part E3. The fourth prat E4 may be parallel to the sixth part E6. The sixth part E6 may be spaced apart from the fourth part E4. The fifth part E5 may connect the fourth part E4 and the sixth part E6.

The fourth part E4, the fifth part E5, and the sixth part E6 may define one edge of the flat part 130P. The first part E1, the second part E2, and the third part E3 may define one edge of the receiving part 137a, 137b. The seventh part E7 and the eighth part E8 may define one edge of a step connecting the receiving part 137a, 137b and the flat part 130P.

A second distance D2 from the lower side of the receiving part 137a, 137b to the third part E3 may be greater than a first distance D1 from the lower side of the receiving part 137a, 137b to the first part E1. The first slit SL1 may be parallel to the second slit SL2.

Accordingly, the curve defined by forming the receiving part 137a, 137b may suppress or reduce poor coupling of the display panel 110 to the material complexed panel 130.

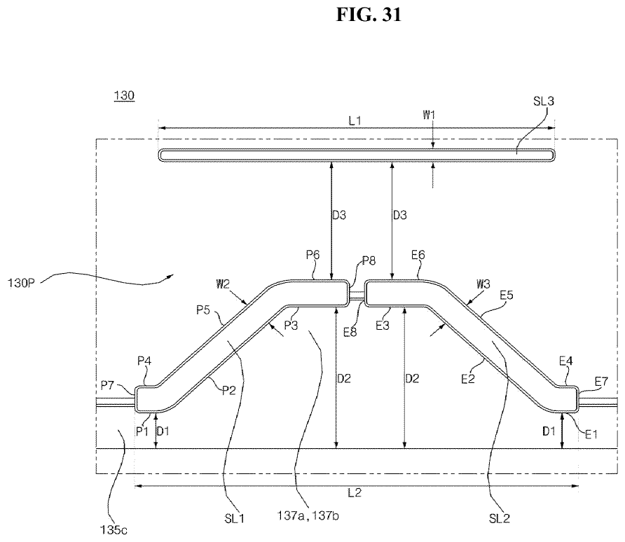

Referring to FIG. 31, the plurality of barrier slits (SL1, SL2) may include a first slit SL1, a second slit SL2, and a third slit SL3. The third slit SL3 may be elongated, and may be spaced apart from the first slit SL1 and the second slit SL2. The third slit SL3 may be disposed opposite the receiving part 137a, 137b with respect to the first slit SL1 and the second slit SL2.

A length L1 of the third slit SL3 may be less than a distance between a seventh part P7 of the first slit SL1 and a seventh part E7 of the second slit SL2. A width w1 of the third slit SL3 may be less than a width w2 of the first slit SL1 and/or a width w3 of the second slit SL2.

A third distance D3 from a sixth part P6 of the first slit SL1 to the third slit SL3 may be less than a second distance D2 from the lower side of the receiving part 137a, 137b to a third part P3 of the first slit SL1.

Accordingly, the curve of the material complexed panel 130 may further suppress or reduce poor coupling of the display panel 110 to the material complexed panel 130.

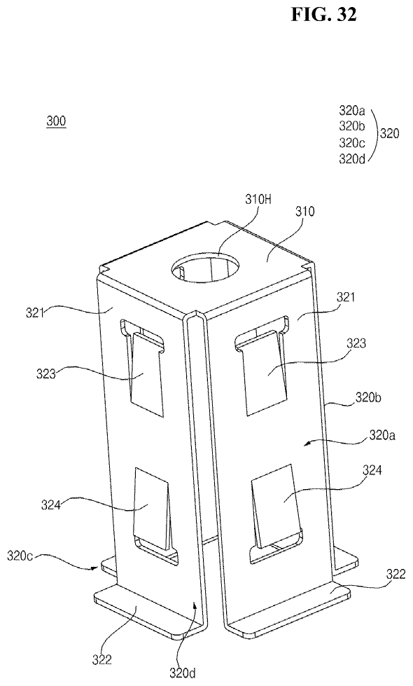

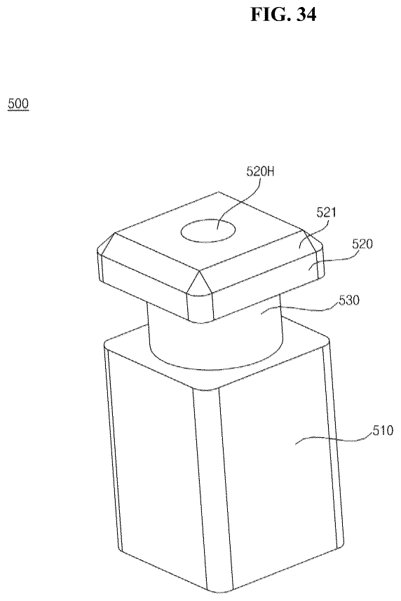

Referring to FIG. 32, a coupling member (300, 500) may include an outer shell 300 and an inner solid 500 (see FIG. 34). The outer shell 300 may be referred to as an outer fixer 300, and the inner solid 500 may be referred to as an inner fixer 500. The coupling member (300, 500) may be referred to as a dual fixer (300, 500).

The outer shell 300 may include a top plate 310 and a side plate 320. The top plate 310 may have a generally quadrangular shape, and may be provided at its center with a through-hole 310H. The side plate 320 may be provided in plurality. The plurality of side plates 320 may be bent and extend from the respective sides of the top plate 310. The plurality of side plates 320 may include a first side plate 320a, a second side plate 320b, a third side plate 320c, and a fourth side plate 320d.

The side plate 320 may include a wall plate 321, an end holder 322, and a side holder 323, 324. The wall plate 321 may be bent and extend from the side of the top plate 310 to thereby define a side surface of the outer shell 300. The end holder 322 may be a supporter bent from an end of the wall plate 321. The end holder 322 may define a bottom surface of the outer shell 300.

The side holder 323, 324 may be cut and bent from the wall plate 321. The side holder 323, 324 may be referred to as a side tab 323, 324. The side holder 323, 324 may be configured as a pair. The pair of side holders 323 and 324 may include an upper holder 323 and a lower holder 324. The upper holder 323 may be referred to as an upper tap 323, and the lower holder 324 may be referred to as a lower tap 324. The left, right and upper sides of the upper holder 323 may be cut to allow the upper holder 323 to bend. An upper end of the upper holder 323 may be a free end. The left, right and lower sides of the lower holder 324 may be cut to allow the lower holder 324 to bend. A lower end of the lower holder 324 may be a free end. The upper holder 323 may be bent to the inside of the outer shell 300, and the upper end of the upper holder 323 may be positioned at the inside of the outer shell 300. The lower holder 324 may be bent to the outside of the outer shell 300, and the lower end of the lower holder 324 may be positioned at the outside of the outer shell 300.

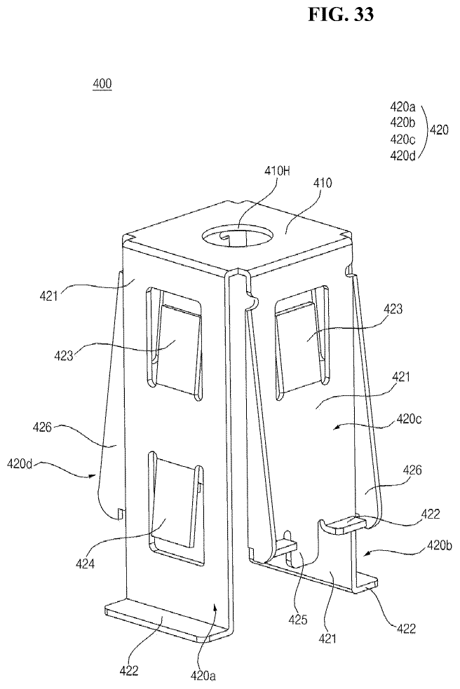

Referring to FIG. 33, a coupling member (400, 500) may include an outer shell 400 and an inner solid 500 (see FIG. 34). The outer shell 400 may be referred to as an outer fixer 400, and the inner solid 500 may be referred to as an inner fixer 500. The coupling member (400, 500) may be referred to as a dual fixer (400, 500).

The outer shell 400 may include a top plate 410 and a side plate 420. The top plate 410 may have a generally quadrangular shape, and may be provided at its center with a through-hole 410H. The side plate 420 may be provided in plurality. The plurality of side plates 420 may be bent and extend from the respective sides of the top plate 410. The plurality of side plates 420 may include a first side plate 420a, a second side plate 420b, a third side plate 420c, and a fourth side plate 420d.

The first side plate 420a or the second side plate 420b may include a wall plate 421, an end holder 422, and a side holder 423, 424. The first side plate 420a may face the second side plate 420b. The first side plate 420a and the second side plate 420b may be symmetric with respect to the top plate 410.

The wall plate 421 may be bent and extend from the side of the top plate 410 to thereby define one side surface of the outer shell 400. The end holder 422 may be a supporter bent from an end of the wall plate 421 to the outside of the outer shell 400. The end holder 422 may define a bottom surface of the outer shell 400.

The side holder 423, 424 may be cut and bent from the wall plate 421. The side holder 423, 424 may be referred to as a side tap 423, 424. The side holder 423, 424 may be configured as a pair. The pair of side holders 423 and 424 may include an upper holder 423 and a lower holder 424. The upper holder 423 may be referred to as an upper tap 423, and the lower holder 424 may be referred to as a lower tap 424. The left, right and upper sides of the upper holder 423 may be cut to allow the upper holder 423 to bend. An upper end of the upper holder 423 may be a free end. The left, right and lower sides of the lower holder 424 may be cut to allow the lower holder 424 to bend. A lower end of the lower holder 424 may be a free end. The upper holder 423 may be bent to the inside of the outer shell 400, and the upper end of the upper holder 423 may be positioned at the inside of the outer shell 400. The lower holder 424 may be bent to the outside of the outer shell 400, and the lower end of the lower holder 424 may be positioned at the outside of the outer shell 400.

The third side plate 420c or the fourth side plate 420d may include a wall plate 421, an end holder 422, a side holder 423, a side rib 426, and an end tip 425. The third side plate 420c my face the fourth side plate 420d. The third side plate 420c and the fourth side plate 420d may be symmetric with respect to the top plate 410.

A length of the wall plate 421 of the third side plate 420c or the fourth side plate 420d may be less than a length of the wall plate 421 of the first side plate 420a.

The side holder 423 of the third side plate 420c or the fourth side plate 420d may be cut and bent from the wall plate 421. The side holder 423 of the third side plate 420c or the fourth side plate 420d may be referred to as an upper holder 423. The left, right and upper sides of the upper holder 423 may be cut to allow the upper holder 423 to bend. An upper end of the upper holder 423 may be a free end. The upper holder 423 may be bent to the inside of the outer shell 400, and the upper end of the upper holder 423 may be positioned at the inside of the outer shell 400.

The end holder 422 of the third side plate 420c or the fourth side plate 420d may be a supporter bent from an end of the wall plate 421. The end holder 422 may be configured as a pair, and the pair of end holders 422 may be provided at the end of the wall plate 421 with some spacing therebetween. The side rib 426 of the third side plate 420c or the fourth side plate 420d may be formed on a lateral side of the wall plate 421. The side rib 426 may be configured as a pair, so as to be provided on both sides of the wall plate 421. The side rib 426 may gradually increase in width from the top plate 410 toward the end holder 422.

The end tip 425 of the third side plate 420c or the fourth side plate 420d may be positioned between the pair of end holders 422, and may extend from the wall plate 421.

Referring to FIG. 34, the inner solid 500 may include a body 510, a neck 530, and a head 520. The body 510 may correspond to an inner space defined by the outer shell 300, 400 (see FIGS. 32 and 33). For example, the body 510 may be a rectangular column. The head 520 may be inserted into the inner space defined by the outer shell 300, 400, and may contact or support the top plate 310, 410 (see FIGS. 32 and 33) of the outer shell 300, 400. The neck 530 may connect the body 510 and the head 520. Between the body 510 and the head 520, the neck 530 may be formed by removing an outer surface of the body 510 or the head 520 to the inside of the inner solid 500.

A solid hole 520H may be formed in an upper surface of the head 520. The solid hole 520H may correspond to the through-hole 310H, 410H (see FIGS. 32 and 33) of the top plate 310, 410, and may be aligned with the through-hole 310H, 410H of the top plate 310, 410. An edge of the head 520 around the solid hole 520H may be tapered. The head 520 may have a tapered surface 521. Accordingly, the head 520 may be coupled to the top plate 310, 410 without separation.

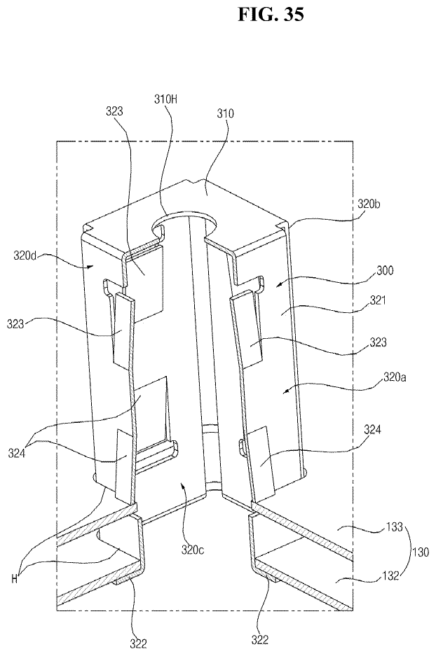

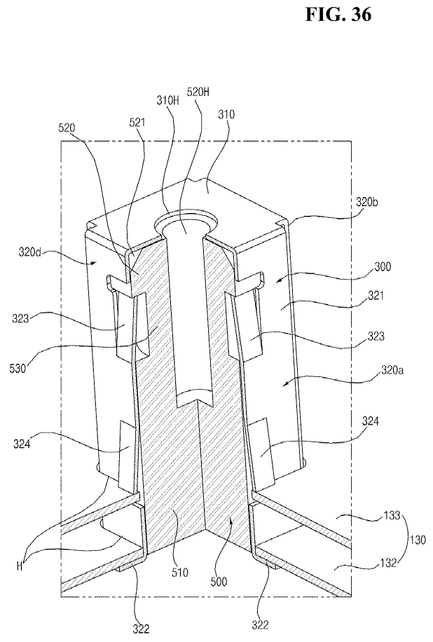

Referring to FIGS. 35 and 36, the outer shell 300 may be coupled to the material complexed panel 130. When the outer shell 300 is inserted into a coupling hole H formed in the material complexed panel 130, the lower holder 324 of the side plate 320 may be engaged with the skin 133, for example, an outer surface of the rear skin 133. A lower side of the lower holder 324 may be supported by the outer surface of the rear skin 133. Also, the end holder 322 of the side plate 320 may be engaged with the skin 132, for example, an outer surface of the front skin 132. An upper surface of the end holder 322 may be in contact with or supported by the outer surface of the front skin 132.

When the inner solid 500 is inserted into the outer shell 300, the upper holder 323 of the side plate 320 may be inserted toward the neck 530 between the head 520 and the body 510 of the inner solid 500. An upper side of the upper holder 323 may be in contact with a lower surface of the head 520 or may be supported by the lower surface of the head 520. The head 520 of the inner solid 500 and the top plate 310 may touch each other. The solid hole 520H of the head 520 may be aligned with the through-hole 310H of the top plate 310.

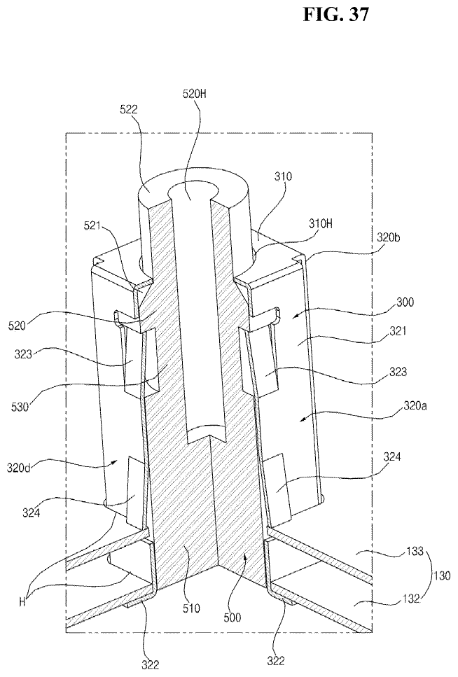

Referring to FIG. 37, the inner solid 500 may include a top pole 522. The top pole 522 may protrude and extend from the upper surface of the head 520. The top pole 522 may be exposed to the outside of the outer shell 300 through the through-hole 310H of the top plate 310. An outer diameter of the top pole 522 may correspond to a diameter of the through-hole 310H of the top plate 310.

Accordingly, the coupling structure may be easily changed through height adjustment of the top pole 522 while allowing an outer structure to be firmly coupled to the inner solid 500a.

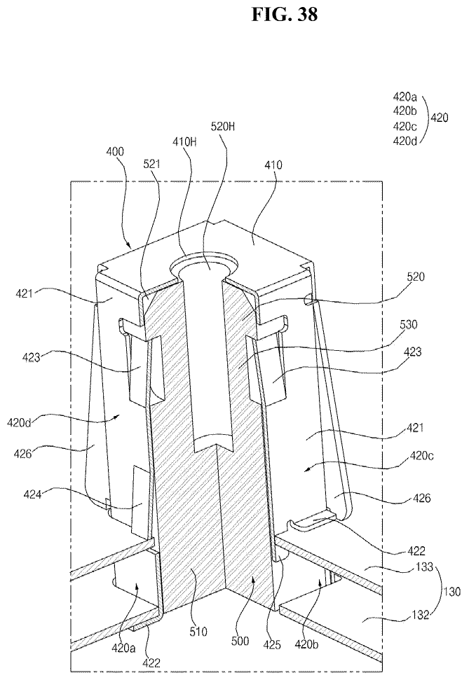

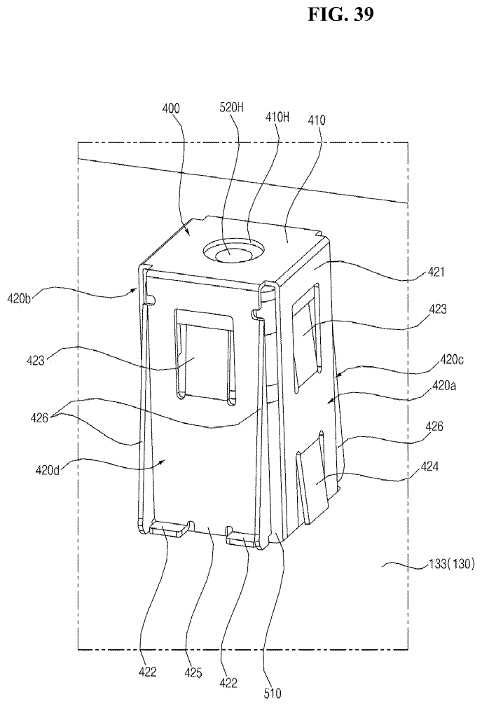

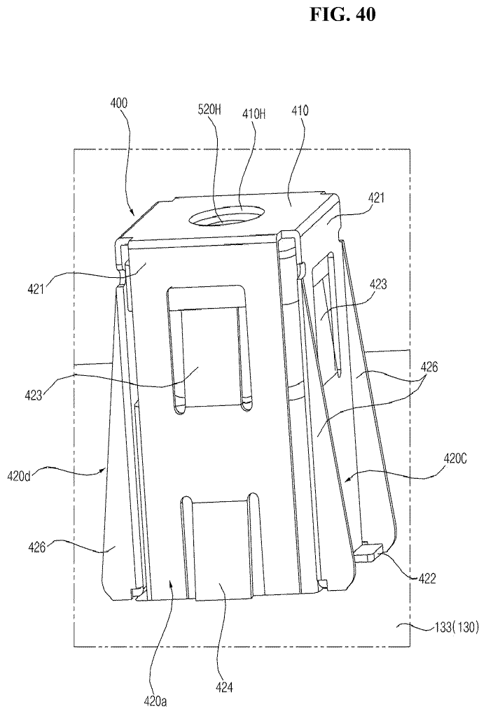

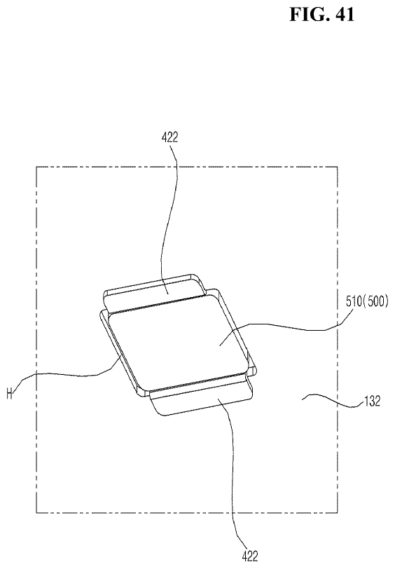

Referring to FIGS. 38 to 41, the outer shell 400 may be coupled to the material complexed panel 130. When the outer shell 400 is inserted into a coupling hole H formed in the material complexed panel 130, the lower holder 424 of the first side plate 420a and/or the second side plate 420b may be engaged with the skin 133, for example, an outer surface of the rear skin 133. A lower side of the lower holder 424 may be supported by the outer surface of the rear skin 133. Also, the end holder 422 of the first side plate 420a and/or the second side plate 420b may be engaged with the skin 132, for example, an outer surface of the front skin 132. An upper surface of the end holder 422 of the first side plate 420a and/or the second side plate 420b may be in contact with or supported by the outer surface of the front skin 132.

When the outer shell 400 is inserted into the material complexed panel 130, the side rib 426 of the third side plate 420c and/or the fourth side plate 420d may be guided along the coupling hole H of the material complexed panel 130, causing the third side plate 420c and/or the fourth side plate 420d to be pushed inside of the outer shell 400.

When an end of the side rib 426 passes through the coupling hole H of the material complexed panel 130, the third side plate 420c and/or the fourth side plate 420d may be returned to its original position by the elastic force, the end tip 425 of the third side plate 420c and/or the fourth side plate 420d may be supported by or in contact with an inner surface of the coupling hole H, and the end holder 422 of the third side plate 420c and/or the fourth side plate 420d may be supported by or in contact with the skin 133, for example, the outer surface of the rear skin 133.

When the inner solid 500 is inserted into the outer shell 400, an outer surface of the body 510 of the inner solid 500 and inner surfaces of the side plates 420 may come in contact with each other, allowing the side plates 420 to be more firmly coupled to the coupling hole H of the material complexed panel 130. That is, the inner solid 500 may prevent the side plates 420 from being moved inside of the outer shell 400. The third side plate 420c and/or the fourth side plate 420d may not be pushed inside of the outer shell 400, thereby preventing the separation of the outer shell 400 from the coupling hole H of the material complexed panel 130.

When the inner solid 500 is inserted into the outer shell 400, the upper holder 423 of the side plate 420 may be inserted toward the neck 530 between the head 520 and the body 510 of the inner solid 500. An upper side of the upper holder 423 may be in contact with or supported by a lower surface of the head 520. The head 520 of the inner solid 500 and the top plate 410 may touch each other. The solid hole 520H of the head 520 may be aligned with the through-hole 410H of the top plate 410.

Accordingly, the inner solid 500 and the outer shell 400 may be firmly or securely coupled to the material complexed panel 130. In a state where the coupling member 400, 500 is coupled to the material complexed panel 130, the coupling member 400, 500 may withstand not only a vertical external force applied in a longitudinal direction of the coupling member 400, 500, but also a moment force or a horizontal external force applied to the coupling member 400, 500.

Referring to FIGS. 1 to 41, a display device may include: a display panel; a material complexed plate to which the display panel is coupled; and a coupling member coupled to the material complexed plate. The material complexed plate may include: a front skin that defines a front surface of the material complexed plate; a rear skin that defines a rear surface of the material complexed plate, the rear skin facing the front skin; a core positioned between the front skin and the rear skin, the core including fibers; and a coupling hole formed through the front skin, the rear skin, and the core. The coupling member may include: an outer shell inserted into the coupling hole and coupled to at least one of the front skin or the rear skin; and an inner solid inserted into the outer shell and coupled to the outer shell.

The outer shell may include: a plurality of side plates extending from the front skin toward the rear skin with respect to a widthwise direction of the material complexed plate, the plurality of side plates being exposed to an outside of the rear skin; and a top plate disposed opposite the front skin with respect to the rear skin so as to face the coupling hole, the top plate connecting the plurality of side plates.

The plurality of side plates may each include: a wall plate bent and extending from the top plate, the wall plate being supported by an edge of the coupling hole of the material complexed plate; and a plurality of side holders formed as the wall plate is cut and bent. The plurality of side holders may include: a lower holder having a lower side that protrudes from the wall plate to an outside of the outer shell so that the lower side of the lower holder is supported by the rear skin; and an upper holder having an upper side that protrudes from the wall plate to an inside of the outer shell so that the upper side of the upper holder is supported by the inner solid.

The inner solid may include: a head facing the top plate; a neck connected to the head; and a body connected to the neck. The neck may include a step formed from an outer surface of the head or an outer surface of the body to an inside of the inner solid. The upper side of the upper holder may be inserted into the step defined by the head and the neck, so as to support a lower surface of the head.

The plurality of side plates may each include an end holder formed by being bent from an end of the wall plate, the end holder being supported by an outer surface of the front skin.

The top plate may include a through-hole. The inner solid may include a solid hole that is aligned with the through-hole and formed in the head facing the top plate.

The plurality of side plates may each include: a wall plate bent and extending from the top plate, the wall plate being supported by an edge of the coupling hole of the material complexed plate; and an upper holder formed as the wall plate is cut and bent, the upper holder having an upper side that protrudes from the wall plate to an inside of the outer shell so that the upper side of the upper holder is supported by the inner solid.

At least one of the plurality of side plates may include a lower holder formed as the wall plate is cut and bent, the lower holder having a lower side that protrudes from the wall plate to an outside of the outer shell so that the lower side of the lower holder is supported by the rear skin.

The at least one of the plurality of side plates may further include an end holder formed as an end of the wall plate is bent, the end holder being supported by an outer surface of the front skin.

Another of the plurality of side plates may further include an end holder formed as an end of the wall plate is bent, the end holder being supported by an outer surface of the rear skin.

The another of the plurality of side plates may further include an end tip extending from the end of the wall plate, the end tip being supported by an edge of the coupling hole of the rear skin.

The another of the plurality of side plates may further include a side rib extending from the upper holder toward the end holder, the side rib being formed as a lateral side of the wall plate is bent. The side rib may gradually increase in width from the upper holder toward the end holder.

The inner solid may include: a head facing the top plate; a neck connected to the head; and a body connected to the neck. The neck may include a step formed from an outer surface of the head or an outer surface of the body to an inside of the inner solid. The upper side of the upper holder may be inserted into the step defined by the head and the neck, so as to support a lower surface of the head.

The top plate may include a through-hole, and the inner solid may include a solid hole that is aligned with the through-hole and formed in the head facing the top plate.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings, and a configuration “B” described in another embodiment of the disclosure and the drawings may be combined with each other. Namely, although the combination between the configurations is not directly described, the combination is possible except in the case where it is described that the combination is impossible.

The above detailed description is to be construed in all aspects as illustrative and not restrictive. The scope of the preset disclosure should be determined by reasonable interpretation of the appended claims, and all changes coming within the equivalency range of the present disclosure are intended to be embraced in the scope of the present disclosure.

What is claimed is:

1. A display device comprising:
a display panel;
a material complexed plate to which the display panel is coupled; and
a coupling member coupled to the material complexed plate,
wherein the material complexed plate comprises:
a front skin that defines a front surface of the material complexed plate;
a rear skin that defines a rear surface of the material complexed plate, the rear skin facing the front skin;
a core positioned between the front skin and the rear skin, the core including fibers; and
a coupling hole formed through the front skin, the rear skin, and the core, and
wherein the coupling member comprises:
an outer shell inserted into the coupling hole and coupled to at least one of the front skin or the rear skin; and
an inner solid inserted into the outer shell and coupled to the outer shell.

2. The display device of claim 1, wherein the outer shell comprises:
a plurality of side plates extending from the front skin toward the rear skin with respect to a widthwise direction of the material complexed plate, the plurality of side plates being exposed to an outside of the rear skin; and
a top plate disposed opposite the front skin with respect to the rear skin so as to face the coupling hole, the top plate connecting the plurality of side plates.

3. The display device of claim 2, wherein the plurality of side plates each comprise:
a wall plate bent and extending from the top plate, the wall plate being supported by an edge of the coupling hole of the material complexed plate; and
a plurality of side holders formed as the wall plate is cut and bent, and
wherein the plurality of side holders comprises:
a lower holder having a lower side that protrudes from the wall plate to an outside of the outer shell so that the lower side of the lower holder is supported by the rear skin; and
an upper holder having an upper side that protrudes from the wall plate to an inside of the outer shell so that the upper side of the upper holder is supported by the inner solid.

4. The display device of claim 3, wherein the inner solid comprises:
a head facing the top plate;
a neck connected to the head; and
a body connected to the neck,
wherein the neck includes a step formed from an outer surface of the head or an outer surface of the body to an inside of the inner solid, and
wherein the upper side of the upper holder is inserted into the step defined by the head and the neck, so as to support a lower surface of the head.

5. The display device of claim 3, wherein the plurality of side plates each comprise an end holder formed by being bent from an end of the wall plate, the end holder being supported by an outer surface of the front skin.

6. The display device of claim 4, wherein the top plate includes a through-hole, and
wherein the inner solid includes a solid hole that is aligned with the through-hole and formed in the head facing the top plate.

7. The display device of claim 2, wherein the plurality of side plates each comprise:
a wall plate bent and extending from the top plate, the wall plate being supported by an edge of the coupling hole of the material complexed plate; and
an upper holder formed as the wall plate is cut and bent, the upper holder having an upper side that protrudes from the wall plate to an inside of the outer shell so that the upper side of the upper holder is supported by the inner solid.

8. The display device of claim 7, wherein at least one of the plurality of side plates comprises a lower holder formed as the wall plate is cut and bent, the lower holder having a lower side that protrudes from the wall plate to an outside of the outer shell so that the lower side of the lower holder is supported by the rear skin.

9. The display device of claim 8, wherein the at least one of the plurality of side plates further comprises an end holder formed as an end of the wall plate is bent, the end holder being supported by an outer surface of the front skin.

10. The display device of claim 8, wherein another of the plurality of side plates further comprises an end holder formed as an end of the wall plate is bent, the end holder being supported by an outer surface of the rear skin.

11. The display device of claim 10, wherein the another of the plurality of side plates further comprises an end tip extending from the end of the wall plate, the end tip being supported by an edge of the coupling hole of the rear skin.

12. The display device of claim 10, wherein the another of the plurality of side plates further comprises a side rib extending from the upper holder toward the end holder, the side rib being formed as a lateral side of the wall plate is bent, and
wherein the side rib gradually increases in width from the upper holder toward the end holder.

13. The display device of claim 12, wherein the inner solid comprises:
a head facing the top plate;
a neck connected to the head; and
a body connected to the neck,
wherein the neck includes a step formed from an outer surface of the head or an outer surface of the body to an inside of the inner solid, and
wherein the upper side of the upper holder is inserted into the step defined by the head and the neck, so as to support a lower surface of the head.

14. The display device of claim 13, wherein the top plate includes a through-hole, and
wherein the inner solid includes a solid hole that is aligned with the through-hole and formed in the head facing the top plate.
